(19) United States
(12) Patent Application Publication
(10) Pub. No.: US 2025/0079302 A1
(43) Pub. Date: Mar. 6, 2025

(54) SEMICONDUCTOR DEVICE

(71) Applicant: Samsung Electronics Co., Ltd., Suwon-si (KR)

(72) Inventors: Byoungjae BAE, Suwon-si (KR); Jin-Wook YANG, Suwon-si (KR); Seung Pil KO, Suwon-si (KR); Yongjae KIM, Suwon-si (KR); Junho PARK, Suwon-si (KR); Kilho LEE, Suwon-si (KR)

(73) Assignee: Samsung Electronics Co., Ltd., Suwon-si (KR)

(21) Appl. No.: 18/444,990

(22) Filed: Feb. 19, 2024

(30) Foreign Application Priority Data
Sep. 5, 2023 (KR) 10-2023-0117952

(51) Int. Cl. H01L 23/528; H01L 23/48; H01L 29/417; H10B 61/00

(52) U.S. Cl. CPC H01L 23/528; H01L 23/481; H10B 61/22; H10D 64/254

(57) ABSTRACT

A semiconductor device includes a substrate having a top surface and a bottom surface opposite to each other, a gate structure on the top surface of the substrate, a plurality of source/drain patterns on the top surface of the substrate and on opposite sides of the gate structure, a backside conductive line on the bottom surface of the substrate and electrically connected to at least one of the gate structure or a first source/drain pattern of the source/drain patterns, and a magnetic tunnel junction pattern electrically connected to a second source/drain pattern of the source/drain patterns.

### CROSS-REFERENCE TO RELATED APPLICATION

This U.S. nonprovisional application claims priority under 35 U.S.C § 119 to Korean Patent Application No. 10-2023-0117952 filed on Sep. 5, 2023 in the Korean Intellectual Property Office, the disclosure of which is hereby incorporated by reference in its entirety.

### BACKGROUND

Various example embodiments relate to a semiconductor device and/or to a method of fabricating the same, and more particularly, to a semiconductor device including a magnetic tunnel junction and/or a method of fabricating the same.

As electronic products trend toward high speed and/or low power consumption, high speed and low operating voltages are increasingly required or expected for semiconductor memory devices incorporated in the electronic products. In order to meet or at least partly meet the expectations above, magnetic memory devices have been developed as semiconductor memory devices. Because magnetic memory devices operate at high speeds and have nonvolatile characteristics, they have attracted considerable attention as the next-generation semiconductor memory devices.

In general, the magnetic memory device may include a magnetic tunnel junction (MTJ) pattern. The magnetic tunnel junction pattern includes two magnetic structures and an insulation layer interposed therebetween. The resistance of the magnetic tunnel junction pattern varies depending on magnetization directions of the two magnetic structures. For example, the magnetic tunnel junction pattern has high resistance when the magnetization directions of the two magnetic structures are anti-parallel and low resistance when the magnetization directions of the two magnetic structures are parallel. The magnetic memory device may write and read data using the resistance difference between the high and low resistances of the magnetic tunnel junction.

According to various demands or expectations of electronic industry, diverse studies are being conducted on semiconductor devices having an embedded structure in which a magnetic tunnel junction pattern is disposed between metal lines.

### SUMMARY

Some example embodiments provide a semiconductor device having improved electrical properties and/or a method of fabricating the same.

Alternatively or additionally, some example embodiments may provide a semiconductor device including magnetic tunnel junction patterns with different switching characteristics and a method of fabricating the same.

According to some example embodiments, a semiconductor device may include a substrate having a top surface and a bottom surface opposite to each other; a gate structure on the top surface of the substrate; a plurality of source/drain patterns on the top surface of the substrate and on opposite sides of the gate structure; a backside conductive line on the bottom surface of the substrate and electrically connected to at least one of the gate structure or a first source/drain pattern of the source/drain patterns; and a magnetic tunnel junction pattern electrically connected to a second source/drain pattern of the source/drain patterns.

Alternatively or additionally according to some example embodiments, a semiconductor device may comprise: a substrate having a top surface and a bottom surface opposite to each other; a gate structure on the top surface of the substrate; a plurality of source/drain patterns on the top surface of the substrate and on opposite sides of the gate structure; a frontside conductive line on the top surface of the substrate and electrically connected to at least one of the gate structure or a first source/drain pattern of the source/drain patterns; a backside conductive line on the bottom surface of the substrate and electrically connected to at least one of the first source/drain pattern or the gate structure; and a through via penetrating at least a portion of the substrate and connected to the backside conductive line and the frontside conductive line.

Alternatively or additionally according to some example embodiments, a semiconductor device may comprise: a substrate having a top surface and a bottom surface opposite to each other, the substrate including a first region and a second region horizontally spaced apart from each other; a first transistor on the top surface of the first region of the substrate; a first magnetic tunnel junction pattern on the top surface of the first region of the substrate and connected to a first drain terminal of the first transistor; a first backside conductive line on the bottom surface of the first region of the substrate and connected to at least one of a first source terminal and a first gate terminal of the first transistor; a second transistor on the top surface of the second region of the substrate; and a second magnetic tunnel junction pattern on the bottom surface of the second region of the substrate and connected to a second drain terminal of the second transistor.

### BRIEF DESCRIPTION OF DRAWINGS

FIG. 1 illustrates a circuit diagram showing a unit memory cell of a semiconductor device according to some example embodiments.

FIG. 2 illustrates a plan view showing a semiconductor device according to some example embodiments.

FIGS. 3A, 3B, and 3C illustrate cross-sectional views respectively taken along lines A-A′, B-B′, and C-C′ of FIG. 2.

FIGS. 4A and 4B illustrate cross-sectional views showing examples of a magnetic tunnel junction pattern in a semiconductor device according to some example embodiments.

FIGS. 5A to 5C and 6A to 6C illustrate diagrams showing a method of fabricating a semiconductor device according to some example embodiments.

FIG. 7 illustrates a plan view showing a semiconductor device according to some example embodiments.

FIGS. 8A and 8B illustrate cross-sectional views respectively taken along lines B-B′ and C-C′ of FIG. 7.

FIG. 9 illustrates a plan view showing a semiconductor device according to some example embodiments.

FIG. 10 illustrates a cross-sectional view taken along line C-C′ of FIG. 9.

FIG. 11 illustrates a plan view showing a semiconductor device according to some example embodiments.

FIGS. 12A, 12B, and 12C illustrate cross-sectional views respectively taken along lines A-A′, B-B′, and C-C′ of FIG. 11.

FIGS. 13A, 13B, and 13C illustrate cross-sectional views respectively taken along lines A-A′, B-B′, and C-C′ of FIG. 11, showing a method of fabricating a semiconductor device according to some example embodiments.

FIG. 14 illustrates a plan view showing a semiconductor device according to some example embodiments.

FIGS. 15A, 15B, and 15C illustrate cross-sectional views respectively taken along lines A-A′, B-B′, and C-C′ of FIG. 14.

FIG. 16 illustrates a plan view showing a semiconductor device according to some example embodiments.

FIGS. 17A, 17B, and 17C illustrate cross-sectional views respectively taken along lines A-A′, B-B′, and C-C′ of FIG. 16.

FIGS. 18A, 18B, and 18C illustrate cross-sectional views respectively taken along lines A-A′, B-B′, and C-C′ of FIG. 2, showing a semiconductor device according to some example embodiments.

FIGS. 19A, 19B, and 19C illustrate cross-sectional views respectively taken along lines A-A′, B-B′, and C-C′ of FIG. 2, showing a method of fabricating a semiconductor device according to some example embodiments.

FIGS. 20A and 20B illustrate cross-sectional views respectively taken along lines B-B′ and C-C′ of FIG. 7, showing a semiconductor device according to some example embodiments.

FIG. 21 illustrates a cross-sectional view taken along line C-C′ of FIG. 9, showing a semiconductor device according to some example embodiments.

FIG. 22 illustrates a cross-sectional view taken along line C-C′ of FIG. 9, showing a method of fabricating a semiconductor device according to some example embodiments.

FIGS. 23A, 23B, and 23C illustrate cross-sectional views respectively taken along lines A-A′, B-B′, and C-C′ of FIG. 11, showing a semiconductor device according to some example embodiments.

FIGS. 24A, 24B, and 24C illustrate cross-sectional views respectively taken along lines A-A′, B-B′, and C-C′ of FIG. 14, showing a semiconductor device according to some example embodiments.

FIG. 25 illustrates a simplified plan view showing a semiconductor device according to some example embodiments.

FIG. 26 illustrates a cross-sectional view showing components on a first region and a second region of FIG. 25.

### DETAILED DESCRIPTION OF EXAMPLE EMBODIMENTS

The following will now describe in detail some example embodiments with reference to the accompanying drawings.

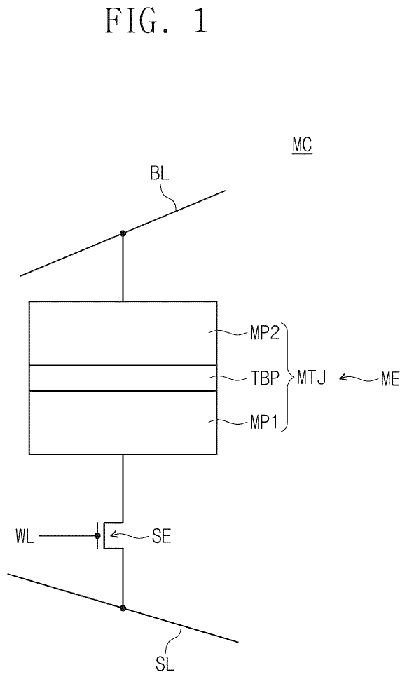

FIG. 1 illustrates a circuit diagram showing a unit memory cell of a semiconductor device according to some example embodiments.

Referring to FIG. 1, a unit memory cell MC may include a memory element ME and a selection element SE. The memory element ME and the selection element SE may be electrically connected in series to each other. The memory element ME may be connected between a bit line BL and the selection element SE. The selection element SE may be connected between the memory element ME and a source line SL, and may be controlled by a row line or word line WL. The selection element SE may be or may include, for example, a bipolar transistor such as an NPN and/or a PNP transistor, and/or may include a metal oxide semiconductor (MOS) field effect transistor such as an NMOS and/or PMOS transistor.

The memory element ME may include a magnetic tunnel junction pattern MTJ including magnetic patterns MP1 and MP2 that are spaced apart from each other and also including a tunnel barrier pattern TBP between the magnetic patterns MP1 and MP2. One of the magnetic patterns MP1 and MP2 may be or may include or be included in a reference magnetic pattern having a magnetization direction that is fixed regardless of an external magnetic field under a normal use environment. Another of the magnetic patterns MP1 and MP2 may be or may include or be included in a free magnetic pattern whose magnetization direction is changed due to an external magnetic field between two stable magnetization directions. The magnetic tunnel junction pattern MTJ may have an electrical resistance whose value is much greater (e.g., several orders of magnitude greater) in a case that the magnetization directions of the reference magnetic pattern and the free magnetic pattern are antiparallel to each other than in a case that the magnetization directions of the reference magnetic pattern and the free magnetic pattern are parallel to each other. For example, the electrical resistance of the magnetic tunnel junction pattern MTJ may be controlled by changing the magnetization direction of the free magnetic pattern. The memory element ME may use the difference in electrical resistance dependent on the magnetization directions of the reference magnetic pattern and the free magnetic pattern, which mechanism may cause the unit memory cell MC to store data therein.

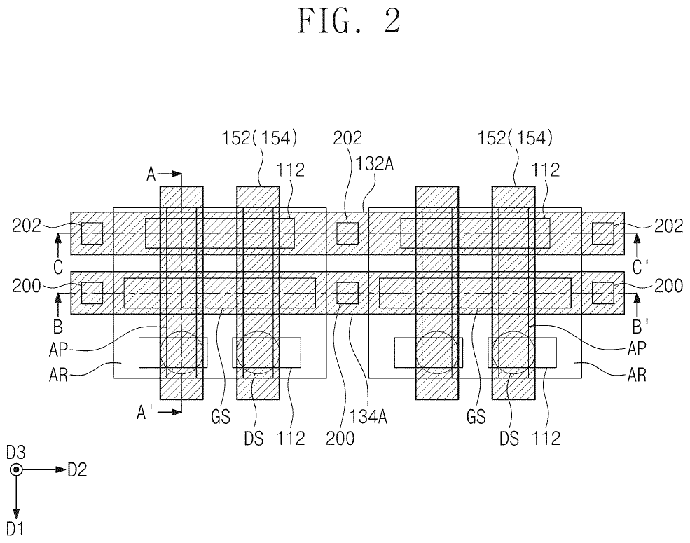

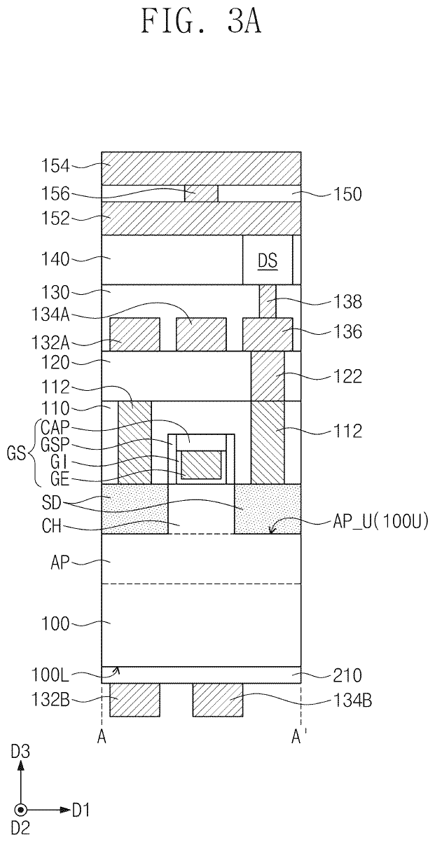

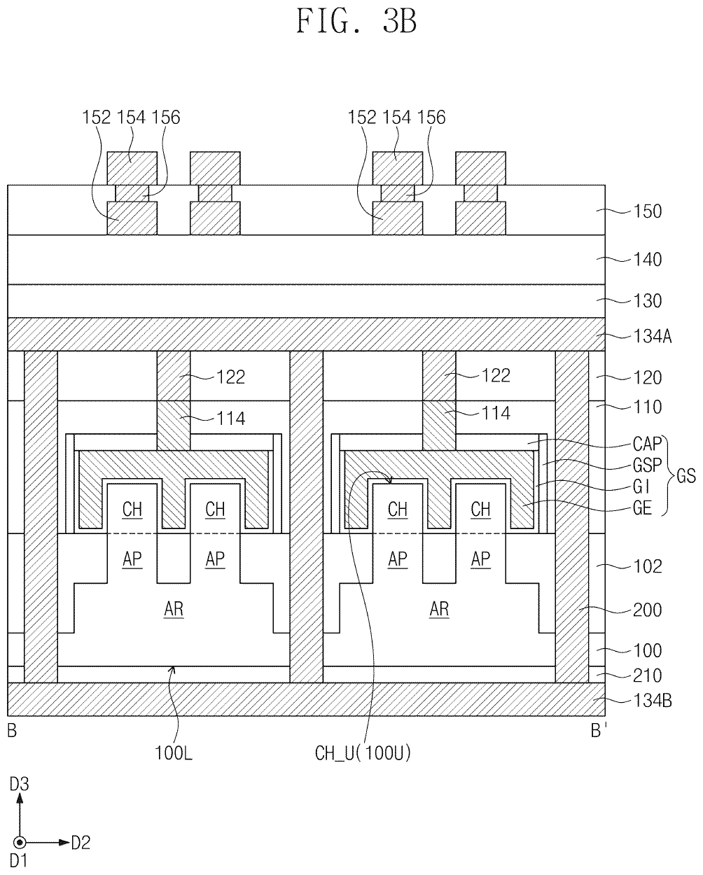

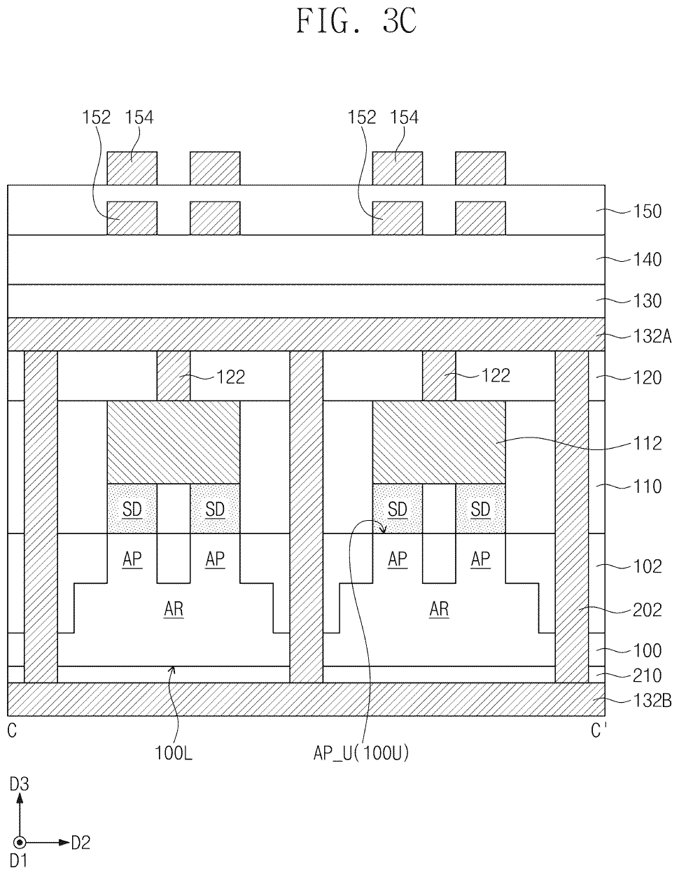

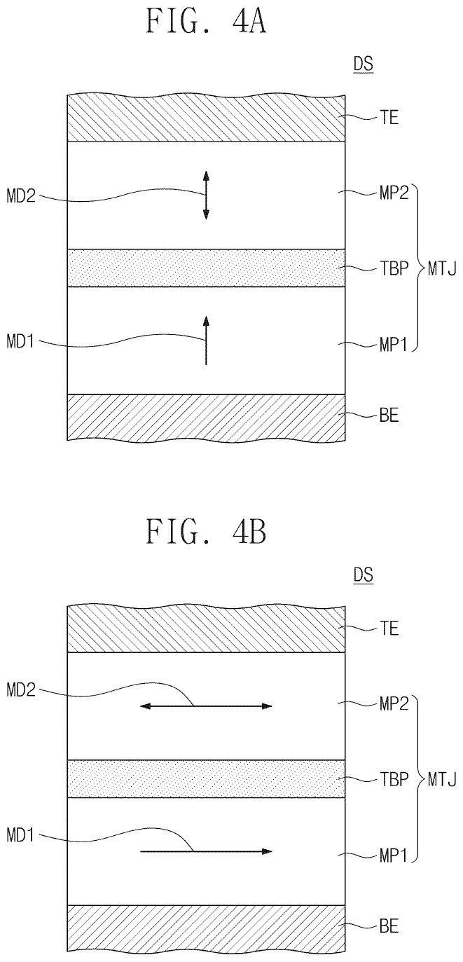

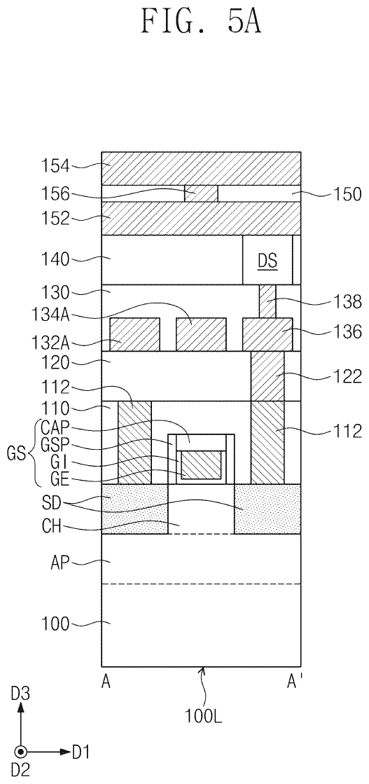

FIG. 2 illustrates a plan view showing a semiconductor device according to some example embodiments. FIGS. 3A, 3B, and 3C illustrate cross-sectional views respectively taken along lines A-A′, B-B′, and C-C′ of FIG. 2. FIGS. 4A and 4B illustrate cross-sectional views showing examples of a magnetic tunnel junction pattern in a semiconductor device according to some example embodiments.

Referring to FIGS. 2 and 3A to 3C, a substrate 100 may be provided which includes active regions AR. The substrate 100 may be or may include a semiconductor substrate such as one or more of a silicon substrate, a germanium substrate, or a silicon-germanium substrate. The substrate 100 may be undoped, or may be doped, e.g., lightly doped with impurities. The substrate 100 may be provided therein with a device isolation layer 102 that defines the active regions AR. The active regions AR may extend in a first direction D1, and may be spaced apart from each other in a second direction D2 across the device isolation layer 102. The first direction D1 and the second directions D2 may be parallel to a bottom surface 100L of the substrate 100, and may intersect each other. The active regions AR may be PMOSFET regions, e.g., regions doped with a high concentration of p-type impurities such as but not limited to boron, or, alternatively, may be NMOSFET regions, e.g., regions doped with a high concentration of n-type impurities such as arsenic and/or phosphorus. The device isolation layer 102 may include at least one selected from a silicon oxide layer, a silicon nitride layer, and a silicon oxynitride layer. In some example embodiments, the device isolation layer 102 may be a shallow trench isolation (STI) layer; example embodiments are not limited thereto.

Active patterns AP may be disposed on the active regions AR. The active patterns AP may protrude in a third direction D3 from corresponding active regions AR, and the third direction D3 may be perpendicular to the bottom surface 100L of the substrate 100. The active patterns AP may extend in the first direction D1 and may be spaced apart from each other in the second direction D2. The device isolation layer 102 may extend onto a top surface of each of the active regions AR and may cover lateral surfaces of the active patterns AP. The active regions AR and the active patterns AP may be or may correspond to portions of the substrate 100 that protrude in the third direction D3 from a lower portion of the substrate 100.

Each of the active patterns AP may include a channel pattern CH that protrudes in the third direction D3 from a top surface AP_U of a corresponding one of the active patterns AP. The channel pattern CH may be called an active fin. The channel pattern CH may upwardly protrude from the device isolation layer 102, and may not be covered with the device isolation layer 102. For example, the device isolation layer 102 may expose a top surface CH_U and lateral surfaces of the channel pattern CH. Source/drain patterns SD may be correspondingly disposed on top surfaces AP_U of the active patterns AP. The channel pattern CH may be interposed between the source/drain patterns SD. The source/drain patterns SD may be epitaxial patterns such as heterogenous or homogenous epitaxial patterns, e.g., formed by a selective epitaxial growth process in which each active pattern AP is used as a seed. The source/drain patterns SD may include, for example, at least one selected from silicon, silicon-germanium, and silicon carbide. The top surface AP_U of each of the active patterns AP, the top surface CH_U of the channel pattern CH, and the lateral surfaces of the channel pattern CH may be called a top surface 100U of the substrate 100. The top surface 100U of the substrate 100 may stand opposite to the bottom surface 100L of the substrate 100.

A gate structure GS may be disposed on the top surface 100U of the substrate 100. The gate structure GS may extend in the second direction D2 to run across the active patterns AP. The gate structure GS may overlap vertically (e.g., in the third direction D3) with the channel pattern CH. The gate structure GS may cover the top surface CH_U and the lateral surfaces of the channel pattern CH, and may extend onto a top surface of the device isolation layer 102. The source/drain patterns SD may be disposed on opposite sides of the gate structure GS.

The gate structure GS may include a gate electrode GE, a gate dielectric pattern GI between the gate electrode GE and the channel pattern CH, gate spacers GSP on lateral surfaces of the gate electrode GE, and a gate capping pattern CAP on a top surface of the gate electrode GE. The gate dielectric pattern GI may extend between the gate electrode GE and the gate spacers GSP, and may have an uppermost surface substantially coplanar with the top surface of the gate electrode GE. The gate electrode GE may cover the top surface CH_U and the lateral surfaces of the channel pattern CH, and may extend onto the top surface of the device isolation layer 102. The gate dielectric pattern GI may be interposed between the gate electrode GE and the top surface CH_U of the channel pattern CH and between the gate electrode GE and each of the lateral surfaces of the channel pattern CH, and may extend between the gate electrode GE and the top surface of the device isolation layer 102.

The gate structure GS, the channel pattern CH, and the source/drain patterns SD may constitute or be included in a fin field effect transistor (FinFET). The gate electrode GE may be called a gate terminal of the transistor, and the source/drain patterns SD may be called source/drain terminals of the transistor.

The gate electrode GE may include one or more of doped semiconductor such as doped polysilicon, conductive metal nitride, and metal. The gate dielectric pattern GI may include at least one selected from a silicon oxide layer, a silicon nitride layer, a silicon oxynitride layer, and a high-k dielectric layer. The high-k dielectric layer may include a material, such as hafnium oxide (HfO), aluminum oxide (AlO), or tantalum oxide (TaO), whose dielectric constant is greater than that of a silicon oxide layer. The gate spacers GSP and the gate capping pattern CAP may each concurrently or independently include at least one selected from a silicon oxide layer, a silicon nitride layer, and a silicon oxynitride layer.

A first interlayer dielectric layer 110 may be disposed on the top surface 100U of the substrate 100, and may cover the gate structure GS, the source/drain patterns SD, and the top surface of the device isolation layer 102. The first interlayer dielectric layer 110 may include, for example, at least one selected from a silicon oxide layer, a silicon nitride layer, a silicon oxynitride layer, and a low-k dielectric layer.

Source/drain contacts 112 may penetrate the first interlayer dielectric layer 110 to come into connection with the source/drain patterns SD. The source/drain contacts 112 may be disposed on opposite sides of the gate structure GS, and may have a bar shape that extends in the second direction D2. A gate contact 114 may penetrate the first interlayer dielectric layer 110 and the gate capping pattern CAP to come into connection with the gate electrode GE. The source/drain contacts 112 and the gate contact 114 may have their top surfaces substantially coplanar with that of the first interlayer dielectric layer 110. For example, the top surfaces of the source/drain patterns 112 and the gate contact 114 may be located at the same height as that of the top surface of the first interlayer dielectric layer 110. As described herein, the term “height” may be a distance measured in the third direction D3 from the bottom surface 100L of the substrate 100. The source/drain contacts 112 and the gate contact 114 may include the same conductive material and may or may not include different materials. The source/drain contacts 112 and the gate contact 114 may include a metallic material, such as at least one selected from aluminum, copper, tungsten, molybdenum, and cobalt.

A second interlayer dielectric layer 120 may be disposed on the first interlayer dielectric layer 110, and may cover the top surfaces of the source/drain contacts and the gate contact 114. The second interlayer dielectric layer 120 may include, for example, at least one selected from a silicon oxide layer, a silicon nitride layer, a silicon oxynitride layer, and a low-k dielectric layer, and may or may not include the same materials as the first interlayer dielectric layer 110.

First via contacts 122 may be disposed in the second interlayer dielectric layer 120. Each of the first via contacts 122 may penetrate the second interlayer dielectric layer 120 to come into connection with a corresponding one of the source/drain contacts 112 and the gate contact 114. The first via contacts 122 may include a conductive material (e.g., metal such as one or more of aluminum, tungsten, or copper).

The second interlayer dielectric layer 120 may be provided thereon with frontside conductive lines 132A and 134A and a first conductive line 136. The frontside conductive lines 132A and 134A and the first conductive line 136 may be located at the same height from the bottom surface 100L of the substrate 100. The frontside conductive lines 132A and 134A and the first conductive line 136 may include the same conductive material, such as metal, and may or may not include different materials. The frontside conductive lines 132A and 134A may include a frontside source line 132A and a frontside word line 134A. The frontside source line 132A and the frontside word line 134A may extend in the second direction D2 and may be spaced apart from each other in the first direction D1.

The frontside source line 132A may be connected through a corresponding one of the first via contacts 122 to a first one of the source/drain contacts 112, and may be electrically connected through the first source/drain contact 112 to a first one of the source/drain patterns SD. In some example embodiments, the first source/drain contact 112 may be called a source contact, and the first source/drain pattern SD may be called a source pattern or a source terminal.

The frontside word line 134A may be connected to the gate contact 114 through a corresponding one of the first via contacts 112, and may be electrically connected through the gate contact 114 to the gate structure GS (e.g., the gate electrode GE).

The first conductive line 136 may be connected through a corresponding one of the first via contacts 122 to a second one of the source/drain patterns 112, and may be electrically connected through the second source/drain contact 112 to a second one of the source/drain patterns SD. In some example embodiments, the second source/drain contact 112 may be called a drain contact, and the second source/drain pattern SD may be called a drain pattern or a drain terminal.

A third interlayer dielectric layer 130 may be disposed on the second interlayer dielectric layer 120, and may cover the frontside conductive lines 132A and 134A and the first conductive line 136. The third interlayer dielectric layer 130 may include, for example, at least one selected from a silicon oxide layer, a silicon nitride layer, a silicon oxynitride layer, and a low-k dielectric layer, and may or may not include the same materials as that of the first interlayer dielectric layer 110 and/or the second interlayer dielectric layer 120.

A data storage pattern DS may be disposed on the third interlayer dielectric layer 130, and a lower electrode contact 138 may be disposed in the third interlayer dielectric layer 130 and below the data storage pattern DS. The lower electrode contact 138 may penetrate the third interlayer dielectric layer 130 to come into connection with the first conductive line 136 and the data storage pattern DS. The lower electrode contact 138 may include at least one of doped semiconductor materials (e.g., doped silicon such as doped polysilicon), metals (e.g., tungsten, titanium, and/or tantalum), metal-semiconductor compounds (e.g., metal silicide), and conductive metal nitrides (e.g., titanium nitride, tantalum nitride, and/or tungsten nitride).

The data storage pattern DS may be electrically connected through the lower electrode contact 138 to the first conductive line 136. The first conductive line 136 may be connected to the second source/drain contact 112 through a corresponding one of the first via contacts 122, and may be electrically connected through the second source/drain contact 112 to the second source/drain pattern SD. For example, the data storage pattern DS may be electrically connected to the second source/drain pattern SD through the lower electrode contact 138, the first conductive line 136, the corresponding first via contact 122, and the second source/drain contact 112.

Referring to FIGS. 4A and 4B, the data storage pattern DS may include a bottom electrode BE, a magnetic tunnel junction pattern MTJ, and a top electrode TE that are sequentially stacked in the third direction D3 on the third interlayer dielectric layer 130. The magnetic tunnel junction pattern MTJ may be disposed between the bottom electrode BE and the top electrode TE. The lower electrode contact 138 may be connected to the bottom electrode BE of the data storage pattern DS. The magnetic tunnel junction pattern MTJ may include a first magnetic pattern MP1, a second magnetic pattern MP2, and a tunnel barrier pattern TBP between the first magnetic pattern MP1 and the second magnetic pattern MP2. The first magnetic pattern MP1 may be disposed between the bottom electrode BE and the tunnel barrier pattern TBP, and the second magnetic pattern MP2 may be disposed between the top electrode TE and the tunnel barrier pattern TBP. The bottom electrode BE may include, for example, conductive metal nitride (e.g., titanium nitride and/or tantalum nitride). The top electrode TE may include at least one selected from metal (e.g., one or more of Ta, W, Ru, or Ir) and/or conductive metal nitride (e.g., TiN).

In some example embodiments, the first magnetic pattern MP1 may be a reference layer having a magnetization direction MD1 that is unidirectionally fixed, and the second magnetic pattern MP2 may be a free layer having a magnetization direction MD2 that can be changed to be parallel with or antiparallel with to the magnetization direction MD1 of the first magnetic pattern MP1. FIGS. 4A and 4B show an example in which the second magnetic pattern MP2 is a free layer, but example embodiments are not limited thereto. Differently from that shown in FIGS. 4A and 4B, the first magnetic pattern MP1 may be the free layer and the second magnetic pattern MP2 may be the reference layer.

Referring to FIG. 4A, for example, the magnetization directions MD1 and MD2 of the first and second magnetic patterns MP1 and MP2 may be perpendicular to an interface between the tunnel barrier pattern TBP and the second magnetic pattern MP2. In this case, each of the first and second magnetic patterns MP1 and MP2 may include at least one selected from an intrinsic perpendicular magnetic material and an extrinsic perpendicular magnetic material. The intrinsic perpendicular magnetic material may include a material having a perpendicular magnetization property found even in the absence of an external factor. The intrinsic perpendicular magnetic material may include at least one selected from a perpendicular magnetic material (e.g., one or more of CoFeTb, CoFeGd, CoFeDy), a perpendicular magnetic material having an L1₀ structure, CoPt of a hexagonal close-packed (HCP) lattice structure, and a perpendicular magnetic structure. The perpendicular magnetic material having the L1₀ structure may include at least one selected from FePt of the L1₀ structure, FePd of the L1₀ structure, CoPd of the L1₀ structure, and CoPt of the L1₀ structure. The perpendicular magnetic structure may include magnetic layers and non-magnetic layers that are alternately and repeatedly stacked, e.g., with the same, or different, or varying thicknesses in each layer. For example, the perpendicular magnetic structure may include at least one selected from (Co/Pt) n, (CoFe/Pt)n, (CoFe/Pd)n, (Co/Pd)n, (Co/Ni)n, (CoNi/Pt)n, (CoCr/Pt)n, and (CoCr/Pd)n (where, n is the number of stacked layers). The extrinsic perpendicular magnetic material may include a material having an intrinsic horizontal magnetization property or a perpendicular magnetization property caused by an external factor. For example, the extrinsic perpendicular magnetic material may have a perpendicular magnetization property due to magnetic anisotropy induced by junction between the tunnel barrier pattern TBP and the first magnetic pattern MP1 (or the second magnetic pattern MP2). The extrinsic perpendicular magnetic material may include, for example, CoFeB.

Referring to FIG. 4B, as another example, the magnetization directions MD1 and MD2 of the first and second magnetic patterns MP1 and MP2 may be parallel to the interface between the tunnel barrier pattern TBP and the second magnetic pattern MP2. In this case, each of the first and second magnetic patterns MP1 and MP2 may include a ferromagnetic material. The first magnetic pattern MP1 may further include an antiferromagnetic material for fixing a magnetization direction of the ferromagnetic material in the first magnetic pattern MP1.

Each of the first and second magnetic patterns MP1 and MP2 may include a Heusler alloy including Co. The tunnel barrier pattern TBP may include at least one selected from a magnesium (Mg) oxide layer, a titanium (Ti) oxide layer, an aluminum (Al) oxide layer, a magnesium-zinc (MgZn) oxide layer, and a magnesium-boron (MgB) oxide layer.

Referring back to FIGS. 2 and 3A to 3C, the third interlayer dielectric layer 130 may be provided thereon with a fourth interlayer dielectric layer 140 that covers the data storage pattern DS. The fourth interlayer dielectric layer 140 may include, for example, at least one selected from a silicon oxide layer, a silicon nitride layer, a silicon oxynitride layer, and a low-k dielectric layer.

A first cell conductive line 152 may be provided on the fourth interlayer dielectric layer 140. The first cell conductive line 152 may extend in the first direction D1, and may run across the frontside conductive lines 132A and 134A and the first conductive line 136. The first cell conductive line 152 may be electrically connected to the data storage pattern DS, and may be connected to the top electrode TE of the data storage pattern DS. The first cell conductive line 152 may include a conductive material, such as metal (e.g., copper and/or aluminum and/or tungsten).

The fourth interlayer dielectric layer 140 may be provided thereon with a fifth interlayer dielectric layer 150 that covers the first cell conductive line 152. The fifth interlayer dielectric layer 150 may include, for example, at least one selected from a silicon oxide layer, a silicon nitride layer, a silicon oxynitride layer, and a low-k dielectric layer.

A second cell conductive line 154 may be disposed on the fifth interlayer dielectric layer 150. The second cell conductive line 154 may extend in the first direction D1, and may run across the frontside conductive lines 132A and 134A and the first conductive line 136. The second cell conductive line 154 may overlap vertically (e.g., in the third direction D3) with the first cell conductive line 152.

A second via contact 156 may be disposed in the fifth interlayer dielectric layer 150, and may be interposed between the first cell conductive line 152 and the second cell conductive line 154. The first cell conductive line 152 and the second cell conductive line 154 may be electrically connected to each other through the second via contact 156. The first cell conductive line 152, the second via contact 156, and the second cell conductive line 154 may constitute or correspond to a column line, e.g., a bit line (see the bit line BL of FIG. 1). The second via contact 156 and the second cell conductive line 154 may include a conductive material, such as metal (e.g., copper and/or tungsten and/or aluminum).

Backside conductive lines 132B and 134B may be disposed on the bottom surface 100L of the substrate 100, and a lower dielectric layer 210 may be interposed between the bottom surface 100L of the substrate 100 and the backside conductive lines 132B and 134B. The lower dielectric layer 210 may include at least one selected from a silicon oxide layer, a silicon nitride layer, a silicon oxynitride layer, and a low-k dielectric layer. The backside conductive lines 132B and 134B may include a conductive material (e.g., metal).

The backside conductive lines 132B and 134B may include a backside source line 132B and a backside word line 134B. The backside source line 132B and the backside word line 134B may extend in the second direction D2 and may be spaced apart from each other in the first direction D1. The backside source line 132B may overlap or be overlapped or at least partly overlap vertically (e.g., in the third direction D3) with the frontside source line 132A, and the backside word line 134B may overlap vertically (e.g., in the third direction D3) with the frontside word line 134A.

Through vias 200 and 202 may be provided to penetrate at least a portion of the substrate 100. Each of the through vias 200 and 202 may penetrate the lower dielectric layer 210, the substrate 100, the device isolation layer 102, the first interlayer dielectric layer 110, and the second interlayer dielectric layer 120, and may be connected to a corresponding one of the backside conductive lines 132B and 134B and a corresponding one of the frontside conductive lines 132A and 134A. The through vias 200 and 202 may include first through vias 200 that connect the frontside word line 134A to the backside word line 134B, and may also include second through vias 202 that connect the frontside source line 132A to the backside source line 132B. The first through vias 200 may be spaced apart from each other in the second direction D2 between the frontside word line 134A and the backside word line 134B. Each of the first through vias 200 may penetrate the lower dielectric layer 210, the substrate 100, the device isolation layer 102, the first interlayer dielectric layer 110, and the second interlayer dielectric layer 120, and may be connected to the frontside word line 134A and the backside word line 134B. The second through vias 202 may be spaced apart from each other in the second direction D2 between the frontside source line 132A and the backside source line 132B. Each of the second through vias 202 may penetrate the lower dielectric layer 210, the substrate 100, the device isolation layer 102, the first interlayer dielectric layer 110, and the second interlayer dielectric layer 120, and may be connected to the frontside source line 132A and the backside source line 132B. The through vias 200 and 202 may include a conductive material (e.g., metal such as but not limited to one or more of aluminum, copper, or tungsten).

The backside word line 134B may be connected to the frontside word line 134A through the first through vias 200, and the frontside word line 134A may be electrically connected to the gate structure GS (or the gate electrode GE) through a corresponding first via contact 122 and the gate contact 114. The frontside word line 134A, the backside word line 134B, and the first through vias 200 may constitute or be include in a row line such as a word line (see the word line WL of FIG. 1).

The backside source line 132B may be connected to the frontside source line 132A through the second through vias 202, and the frontside source line 132A may be electrically connected to the first source/drain pattern SD through a corresponding first via contact 122 and the first source/drain contact 112. The frontside source line 132A, the backside source line 132B, and the second through vias 202 may constitute or be included in a source line (see the source line SL of FIG. 1).

According to various example embodiments, the substrate 100 may be provided on its top surface 100U with a transistor including the gate structure GS, the channel pattern CH, and the source/drain patterns SD, and may be provided on its bottom surface 100L with the backside word line 134B and the backside source line 132B. The backside word line 134B and the backside source line 132B may be electrically connected through the through vias 200 and 202 to the frontside word line 134A and the frontside source line 132A, respectively. A word line connected to a gate terminal (such as the gate electrode GE) of the transistor may include the frontside word line 134A, the backside word line 134B, and the first through vias 200. As the word line includes the frontside word line 134A and the backside word line 134B that are connected in parallel to each other, the word line may have a decrease in resistance, which may improve electrical performance. Alternatively or additionally, a source line connected to a source terminal (e.g., the first source/drain pattern SD) of the transistor may include the frontside source line 132A, the backside source line 132B, and the second through vias 202. As the source line includes the frontside source line 132A and the backside source line 132B that are connected in parallel to each other, the source line may have a decrease in resistance, which may improve electrical performance.

It therefore may be possible to provide a semiconductor device with improved electrical properties, such as speed and/or power consumption and/or reliability.

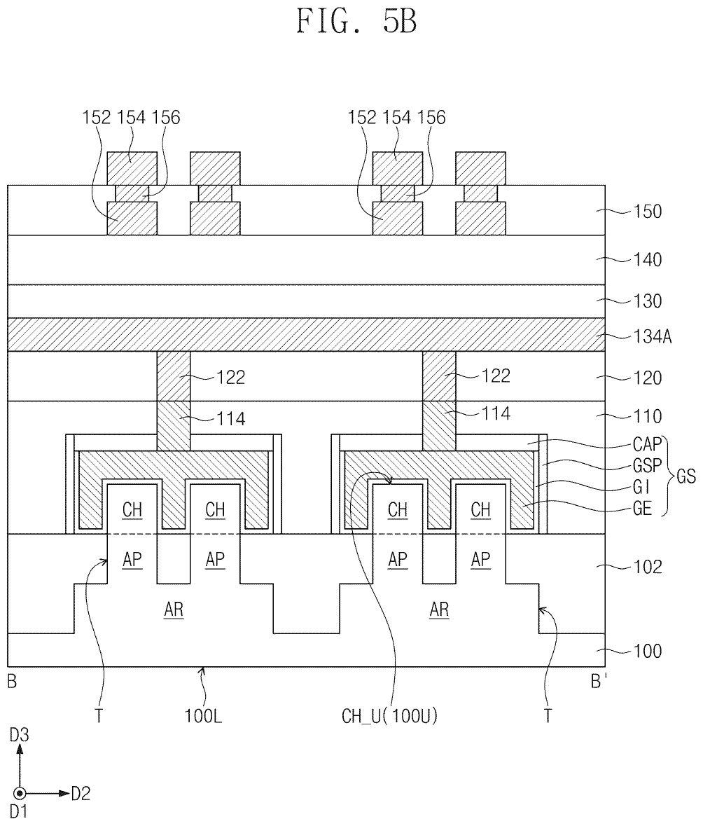

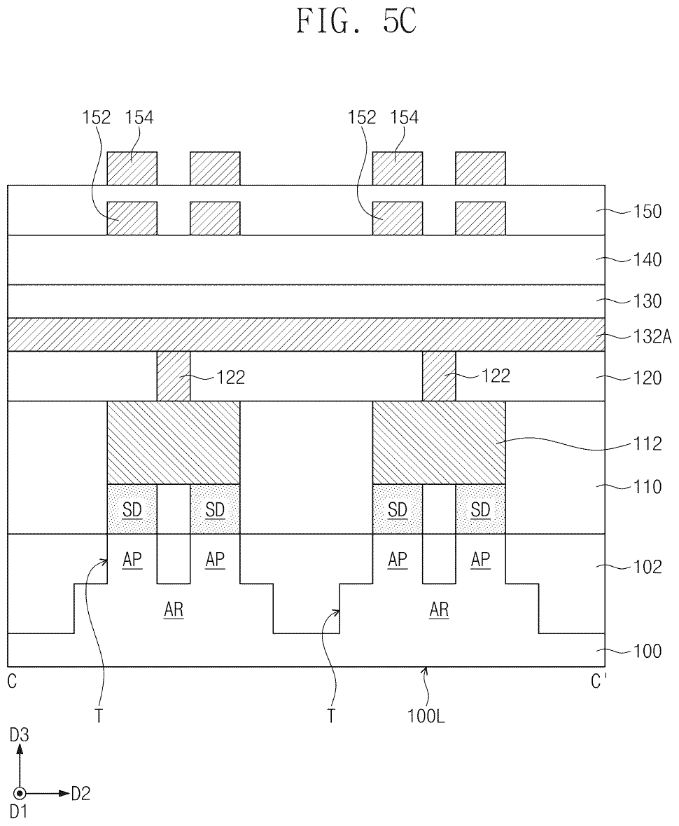

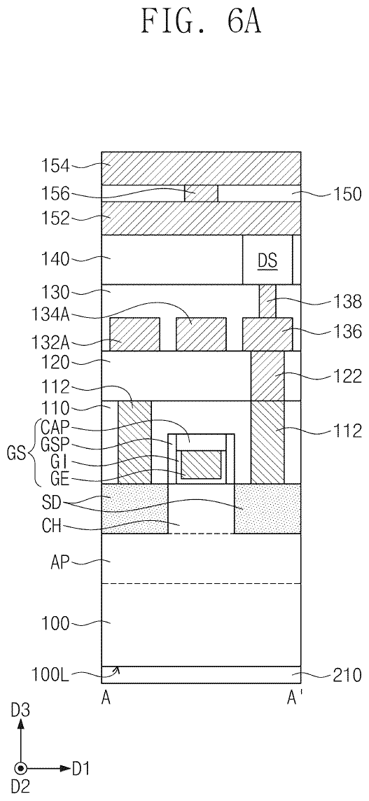

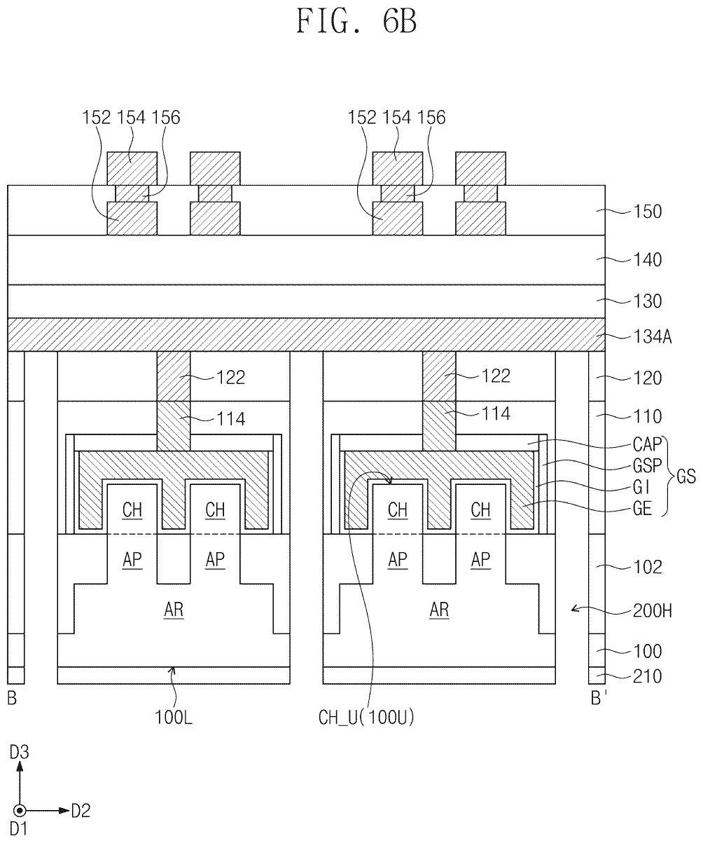

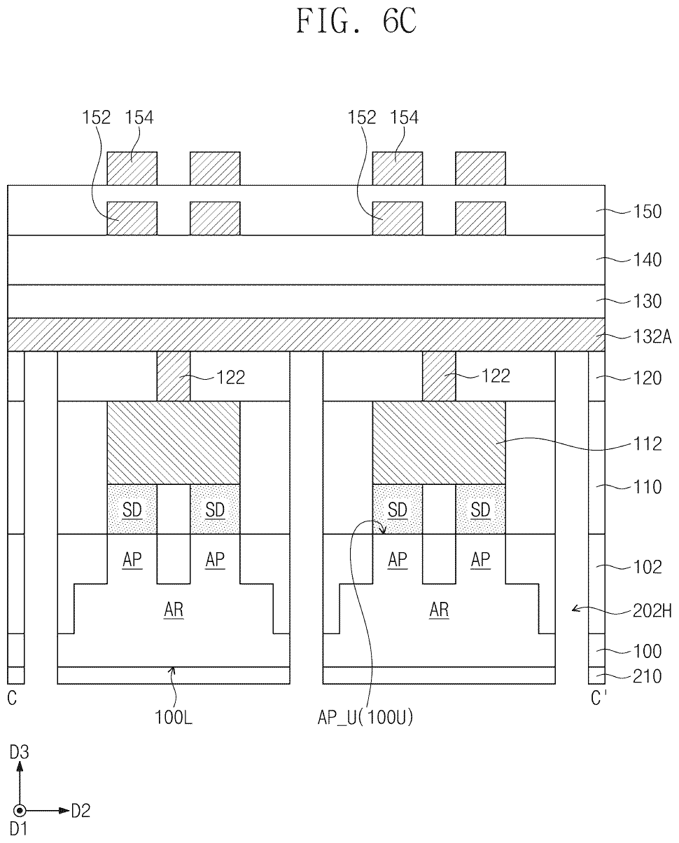

FIGS. 5A to 5C and 6A to 6C illustrate diagrams showing a method of fabricating a semiconductor device according to some example embodiments. FIGS. 5A and 6A illustrate cross-sectional views taken along line A-A′ of FIG. 2. FIGS. 5B and 6B illustrate cross-sectional views taken along line B-B′ of FIG. 2. FIGS. 5C and 6C illustrate cross-sectional views taken along line C-C′ of FIG. 2. A repetitive explanation of those of the semiconductor device discussed with reference to FIGS. 2, 3A, 3B, 3C, 4A, and 4B will be omitted for brevity of description.

Referring to FIGS. 2 and 5A to 5C, trenches T may be formed, e.g., etched, on an upper portion of the substrate 100, and the trenches T may define active regions AR and active patterns AP. The trenches T may be formed by pattering the upper portion of the substrate 100. The active regions AR may extend in a first direction D1 and may be spaced apart from each other in a second direction D2. The active patterns AP may be formed to protrude upwardly (e.g., in a third direction D3) from the active regions AR. The active patterns AP may extend in the first direction D1 and may be spaced apart from each other in the second direction D2.

A device isolation layer 102 may be formed to fill the trenches T. The device isolation layer 102 may be recessed to expose an upper portion of each active pattern AP. In some example embodiments, the device isolation layer 102 may be formed with a shallow trench isolation (STI) process; example embodiments are not limited thereto. A sacrificial gate structure may be formed to run across the active patterns AP. The sacrificial gate structure may include a sacrificial gate pattern that runs across the active patterns AP and gate spacers GSP on lateral surfaces of the sacrificial gate pattern. Source/drain patterns SD may be formed on the active patterns AP on opposite sides of the sacrificial gate structure. The formation of the source/drain patterns SD may include, for example, recessing portions of each active pattern AP on opposite sides of the sacrificial gate structure, and performing a homogenous and/or heterogenous epitaxial growth process on the recessed portions of each active patterns AP. In some example embodiments, the source/drain patterns SD may be doped, e.g., with an ion implantation process and/or an in-situ doping process. An upper portion of each active pattern AP between the source/drain patterns SD may be called a channel pattern CH.

A lower portion of a first interlayer dielectric layer 110 may be formed to cover the sacrificial gate structure and the source/drain patterns SD, and a gate structure GS may be formed in the lower portion of the first interlayer dielectric layer 110. The formation of the gate structure GS may include, for example, removing the sacrificial gate pattern to form an empty space that exposes the channel pattern CH between the gate spacers GSP, and forming a gate dielectric pattern GI, a gate electrode GE, and a gate capping pattern CAP in the empty space. The gate structure GS may include the gate electrode GE that runs across the active patterns AP, the gate dielectric pattern GI between the gate electrode GE and the channel pattern CH, the gate spacers GSP on lateral surfaces of the gate electrode GE, and the gate capping pattern CAP on a top surface of the gate electrode GE. The gate electrode GE may be formed to vertically overlap the channel pattern CH. The gate electrode GE may cover a top surface CH_U of the channel pattern CH, and may cover lateral surfaces of the channel pattern CH that are opposite to each other in the second direction D2. The source/drain patterns SD may be disposed on opposite sides of the gate structure GS. Afterwards, an upper portion of the first interlayer dielectric layer 110 may be formed to cover the gate structure GS.

Source/drain contacts 112 and a gate contact 114 may be formed in the first interlayer dielectric layer 110. The source/drain contacts 112 may penetrate the first interlayer dielectric layer 110 to come into connection with the source/drain patterns SD, and the gate contact 114 may penetrate the first interlayer dielectric layer 110 and the gate capping pattern CAP to come into connection with the gate electrode GE. The formation of the source/drain patterns 112 and the gate contact 114 may include, for example, forming source/drain contact holes to penetrate the first interlayer dielectric layer 110 and to expose the source/drain patterns SD, forming a gate contact hole to penetrate the first interlayer dielectric layer 110 and the gate capping pattern CAP and to expose the gate electrode GE, forming a conductive layer to fill the source/drain contact holes and the gate contact hole, and planarizing the conductive layer until a top surface of the first interlayer dielectric layer 110 is exposed. The planarizing process may be performed with an etch-back process and/or a chemical mechanical planarization (CMP) process; example embodiments are not limited thereto.

A second interlayer dielectric layer 120 may be formed on the first interlayer dielectric layer 110, e.g., with a CVD process, and first via contacts 112 may be formed in the second interlayer dielectric layer 120. Each of the first via contacts 122 may be formed to be connected to a corresponding one of the source/drain patterns 112 and the gate contact 114. The formation of the first via contacts 122 may include, for example, forming first via holes to penetrate the second interlayer dielectric layer 120 and forming a conductive layer to fill the first via hole.

Frontside conductive lines 132A and 134A and a first conductive line 136 may be formed on the second interlayer dielectric layer 120. The formation of the frontside conductive lines 132A and 134A and the first conductive line 136 may include, for example, forming a conductive layer on the second interlayer dielectric layer 120 and patterning the conductive layer. The forming the conductive layer may include a process such as one or more of a chemical vapor deposition (CVD) process and/or a physical vapor deposition (PVD) process; example embodiments are not limited thereto. The frontside conductive lines 132A and 134A may include a frontside source line 132A and a frontside word line 134A. The frontside source line 132A may be connected through a corresponding one of the first via contacts 122 to a first one of the source/drain contacts 112, and may be electrically connected through the first source/drain contact 112 to a first one of the source/drain patterns SD. The frontside word line 134A may be connected to the gate contact 114 through a corresponding one of the first via contacts 112, and may be electrically connected through the gate contact 114 to the gate structure GS (or the gate electrode GE). The first conductive line 136 may be connected through a corresponding one of the first via contacts 122 to a second one of the source/drain patterns 112, and may be electrically connected through the second source/drain contact 112 to a second one of the source/drain patterns SD.

A third interlayer dielectric layer 130 may be formed on the second interlayer dielectric layer 120, e.g., with a CVD process, and may cover the frontside conductive lines 132A and 134A and the first conductive line 136. A lower electrode contact 138 may be formed in the third interlayer dielectric layer 130. A lower electrode contact 138 may be formed to penetrate an upper portion of the third interlayer dielectric layer 130 and to have connection with the first conductive line 136. The formation of the lower electrode contact 138 may include, for example, forming a lower electrode contact hole to penetrate an upper portion of the third interlayer dielectric layer 130 and to expose the first conductive line 136, and forming a conductive layer to fill the lower contact hole.

A data storage pattern DS may be formed on the third interlayer dielectric layer 130. As discussed with reference to FIGS. 4A and 4B, the data storage pattern DS may include a bottom electrode BE, a magnetic tunnel junction pattern MTJ, and a top electrode TE that are sequentially stacked on the third interlayer dielectric layer 130. The formation of the data storage pattern DS may include, for example, sequentially forming a lower electrode layer and a magnetic tunnel junction layer on the third interlayer dielectric layer 130, forming a conductive mask pattern on the magnetic tunnel junction layer, and using the conductive mask pattern as an etching mask to sequentially etch the magnetic tunnel junction layer and the lower electrode layer. The magnetic tunnel junction layer may include a first magnetic layer, a tunnel barrier layer, and a second magnetic layer that are sequentially stacked on the lower electrode layer. The magnetic tunnel junction layer and the lower electrode layer may be formed by, for example, one or more of a sputtering process, a chemical vapor deposition process, or an atomic layer deposition process.

The magnetic tunnel junction layer and the lower electrode layer may be etched to respectively form the magnetic tunnel junction pattern MTJ and the bottom electrode BE. The etching of the magnetic tunnel junction layer may include using the conductive mask pattern as an etching mask to sequentially etch the second magnetic layer, the tunnel barrier layer, and the first magnetic layer. The second magnetic layer, the tunnel barrier layer, and the first magnetic layer may be etched to respectively form a second magnetic pattern MP2, a tunnel barrier pattern TBP, and a first magnetic pattern MP1. The conductive mask pattern may remain on the magnetic tunnel junction pattern MTJ after the magnetic tunnel junction layer and the lower electrode layer are etched, and the remainder of the conductive mask pattern may be defined as the top electrode TE. An ion beam etching process that uses an ion beam may be used to perform an etching process for etching the magnetic tunnel junction layer and the lower electrode layer. The ion beam may include inert ions such as but not limited to a noble gas ion.

A fourth interlayer dielectric layer 140 may be formed on the third interlayer dielectric layer 130, e.g., with a CVD process, and may cover the data storage pattern DS. A first cell conductive line 152 may be formed on the fourth interlayer dielectric layer 140. A fifth interlayer dielectric layer 150 may be formed on the fourth interlayer dielectric layer 140, and may cover the first cell conductive line 152. A second via contact 156 may be formed in the fifth interlayer dielectric layer 150 and on the first cell conductive line 152. A second cell conductive line 154 may be formed on the fifth interlayer dielectric layer 150. The second cell conductive line 154 may overlap vertically (e.g., in the third direction D3) with the first cell conductive line 152. The first cell conductive line 152 and the second cell conductive line 154 may extend in parallel to each other along the first direction D1. The first cell conductive line 152 and the second cell conductive line 154 may be electrically connected to each other through the second via contact 156.

Referring to FIGS. 2 and 6A to 6C, in some example embodiments the front side may have a passivation layer and/or a protective layer formed thereupon, and the substrate may be flipped or rotated. In some example embodiments, a lower dielectric layer 210 may be formed on a bottom surface 100L of the substrate 100. Through via holes 200H and 202H may be formed to penetrate the lower dielectric layer 210 and the substrate 100. The through via holes 200H and 202H may be formed to extend in the third direction D3 and to penetrate the device isolation layer 102, the first interlayer dielectric layer 110, and the second interlayer dielectric layer 120. The through via holes 200H and 202H may include first through via holes 200H that expose a bottom surface of the frontside word line 134A and second through via holes 202H that expose a bottom surface of the frontside source line 132A.

Referring back to FIGS. 2 and 3A to 3C, through vias 200 and 202 may be formed in the through via holes 200H and 202H. The formation of the through vias 200 and 202 may include, for example, forming on the bottom surface 100L of the substrate 100 a conductive layer to fill the through via holes 200H and 202H, and planarizing the conductive layer until the lower dielectric layer 210 is exposed. The through vias 200 and 202 may include first through vias 200 that are spaced apart in the second direction D2 along the bottom surface of the frontside word line 134A and second through vias 202 that are spaced apart from each other in the second direction D2 along the bottom surface of the frontside source line 132A.

Backside conductive lines 132B and 134B may be formed on the bottom surface 100L of the substrate 100, and the lower dielectric layer 210 may be interposed between the bottom surface 100L of the substrate 100 and the backside conductive lines 132B and 134B. The backside conductive lines 132B and 134B may include a backside source line 132B and a backside word line 134B. The backside source line 132B may overlap vertically (e.g., in the third direction D3) with the frontside source line 132A, and the backside word line 134B may overlap vertically (e.g., in the third direction D3) with the frontside word line 134A. The backside word line 134B may be connected to the first through vias 200, and may be electrically connected through the first through vias 200 to the frontside word line 134A. The backside source line 132B may be connected to the second through vias 202, and may be electrically connected through the second through vias 202 to the frontside source line 132A. The formation of the backside conductive lines 132B and 134B may include, for example, forming a backside conductive layer on the lower dielectric layer 210 and patterning the conductive layer.

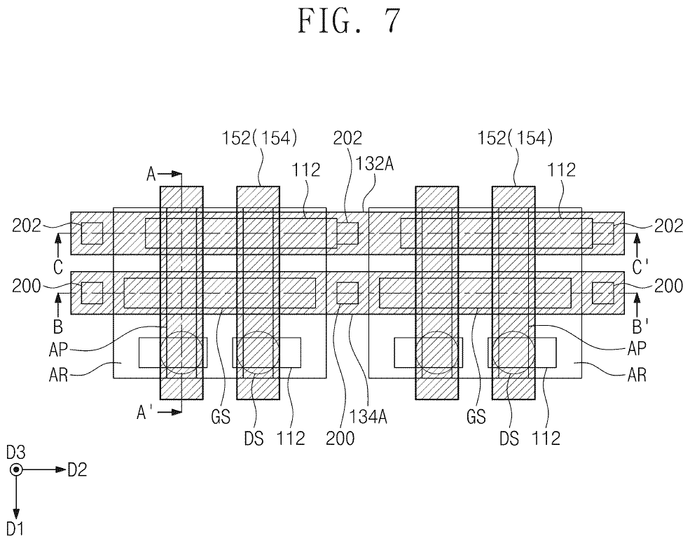

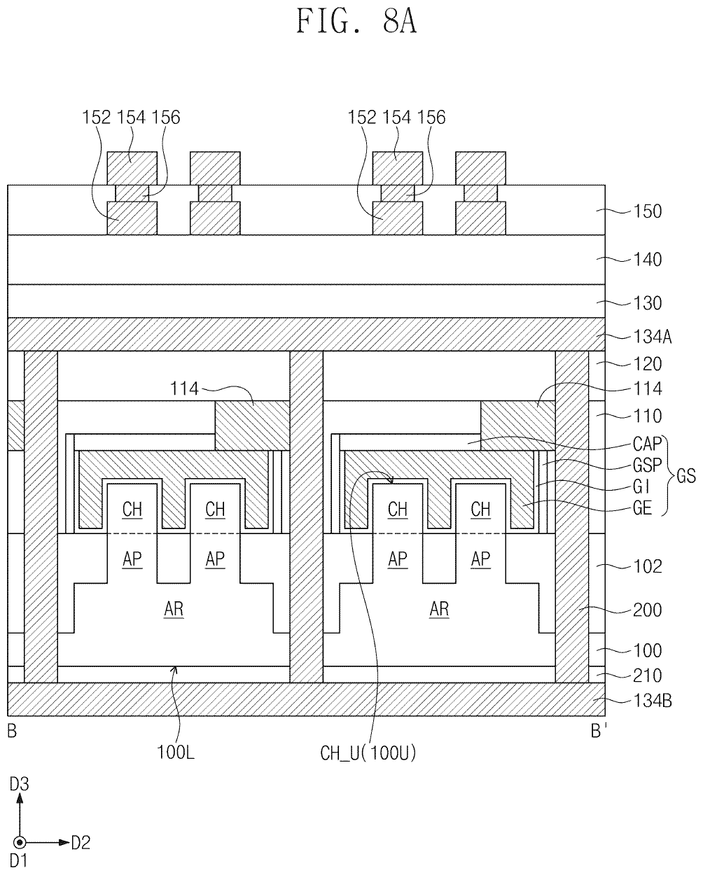

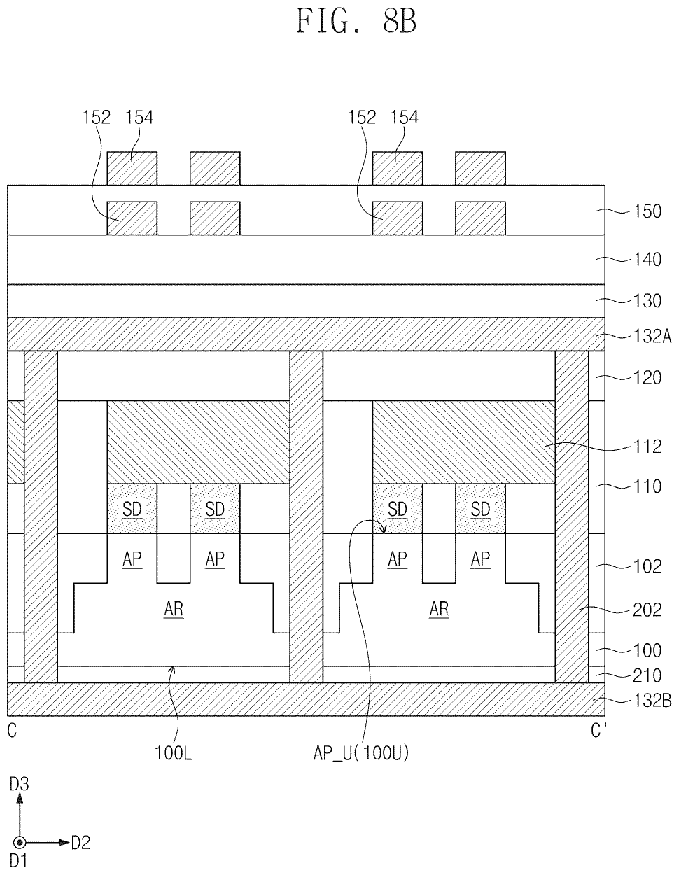

FIG. 7 illustrates a plan view showing a semiconductor device according to some example embodiments. FIGS. 8A and 8B illustrate cross-sectional views taken along lines B-B′ and C-C′ of FIG. 7. A cross-sectional view taken along line A-A′ of FIG. 7 may be substantially the same as that of FIG. 3A. For brevity of description, the following will mainly discuss a difference from the semiconductor device discussed with reference to FIGS. 2, 3A to 3C, 4A, and 4B.

Referring to FIGS. 7, 8A, and 8B, the first through vias 200 may connect the frontside word line 134A to the backside word line 134B, and may be spaced apart from each other in the second direction D2 between the frontside word line 134A and the backside word line 134B. Each of the first through vias 200 may penetrate the lower dielectric layer 210, the substrate 100, the device isolation layer 102, the first interlayer dielectric layer 110, and the second interlayer dielectric layer 120, and may connect the frontside word line 134A to the backside word line 134B. According to some example embodiments, each of the first through vias 200 may be connected to a lateral surface of the gate contact 114. For example, a lateral surface of each of the first through vias 200 may be in contact with the lateral surface of the gate contact 114. The gate contact 114 may not be connected to the first via contacts 122. In this case, the frontside word line 134A and the backside word line 134B may be electrically connected to the gate structure GS (or the gate electrode GE) through the first through vias 200 and the gate contact 114.

The second through vias 202 may connect the frontside source line 132A to the backside source line 132B, and may be spaced apart from each other in the second direction D2 between the frontside source line 132A and the backside source line 132B. Each of the second through vias 202 may penetrate the lower dielectric layer 210, the substrate 100, the device isolation layer 102, the first interlayer dielectric layer 110, and the second interlayer dielectric layer 120, and may connect the frontside source line 132A to the backside source line 132B. According to some example embodiments, each of the second through vias 202 may be connected to a lateral surface of the first source/drain contact 112. For example, a lateral surface of each of the second through vias 202 may be in contact with that of the first source/drain contact 112. The first source/drain contact 112 may not be connected to the first via contacts 122. In this case, the frontside source line 132A and the backside source line 132B may be electrically connected to the first source/drain pattern SD through the second through vias 202 and the first source/drain contact 112.

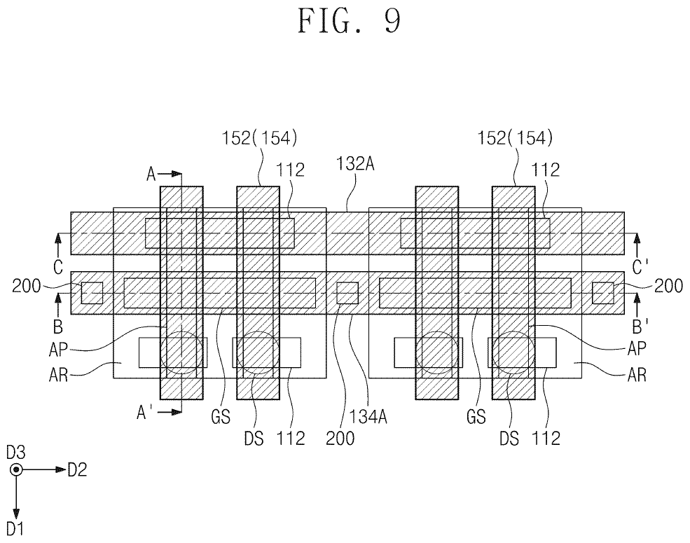

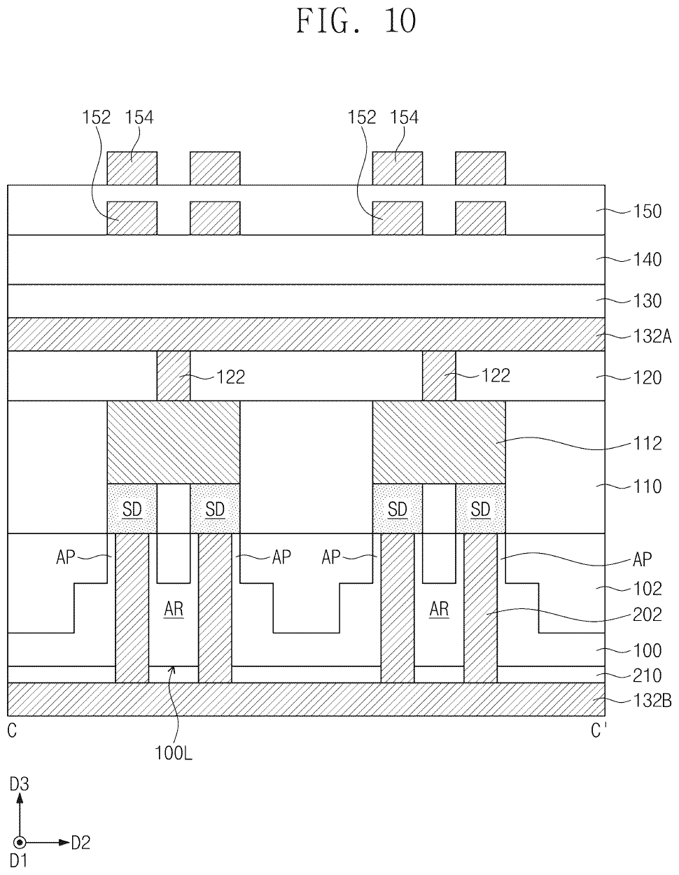

FIG. 9 illustrates a plan view showing a semiconductor device according to some example embodiments. FIG. 10 illustrates a cross-sectional view taken along line C-C′ of FIG. 9. Cross-sectional views taken along lines A-A′ and B-B′ of FIG. 9 may be substantially the same as those of FIGS. 3A and 3B, respectively. For brevity of description, the following will mainly discuss a difference from the semiconductor device discussed with reference to FIGS. 2, 3A to 3C, 4A, and 4B.

Referring to FIGS. 9 and 10, the frontside source line 132A may be connected to a corresponding first via contact 122 to the first source/drain contact 112, and may be electrically connected through the first source/drain contact 112 to the first source/drain pattern SD.

The second through vias 202 may penetrate the lower dielectric layer 210 and the substrate 100, and may be connected to the backside source line 132B. According to some example embodiments, each of the second through vias 202 may penetrate the lower dielectric layer 210, a corresponding active region AR, and a corresponding active pattern AP, and may be connected to the first source/drain pattern SD. The backside source line 132B may be electrically connected through the second through vias 202 to the first source/drain pattern SD.

The first source/drain pattern SD may be interposed between the second through vias 202 and the first source/drain contact 112. The second through vias 202 may be connected to a lower portion of the first source/drain pattern SD, and the first source/drain contact 112 may be connected to an upper portion of the first source/drain pattern SD.

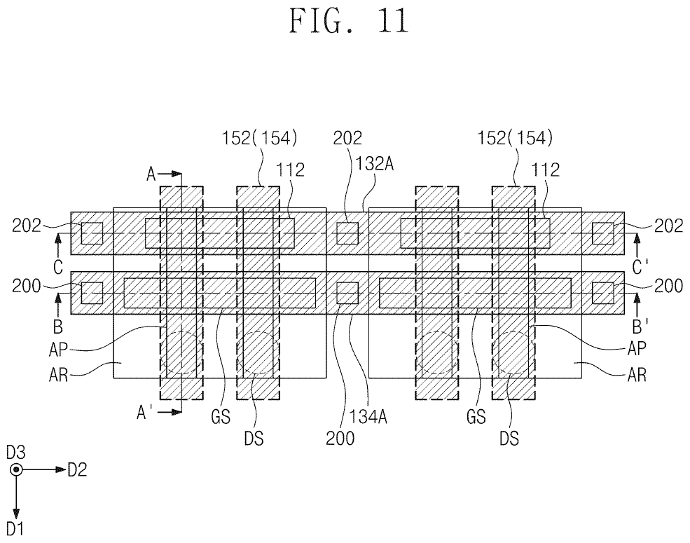

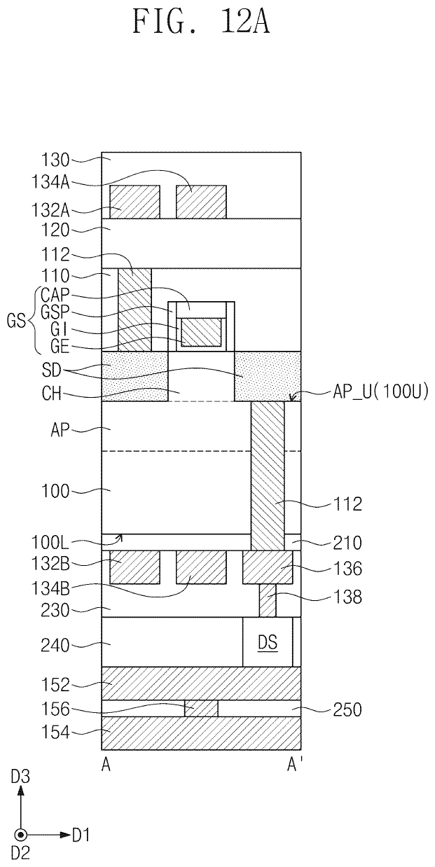

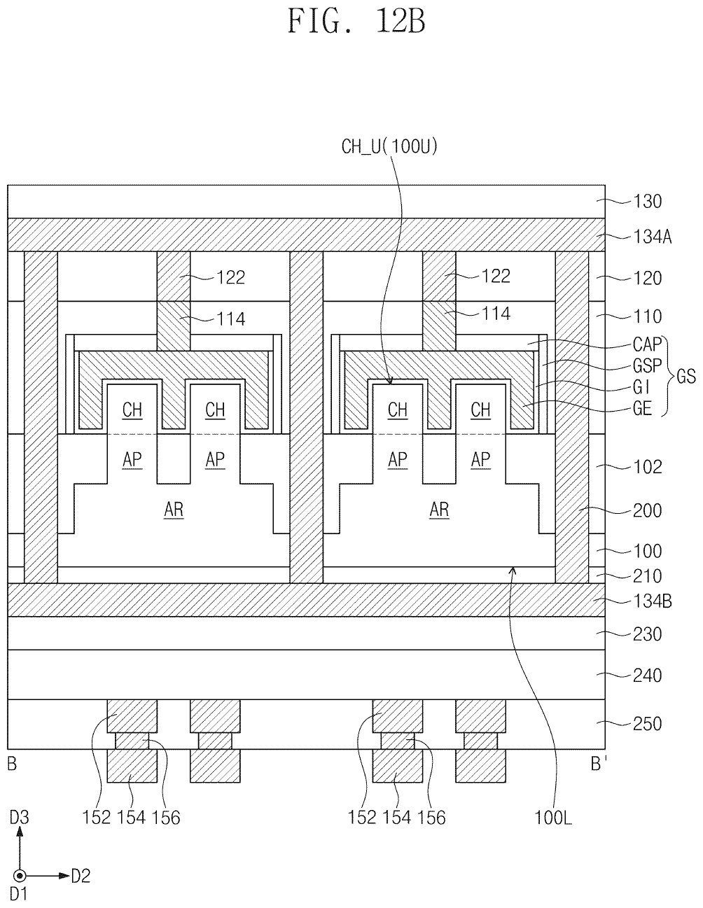

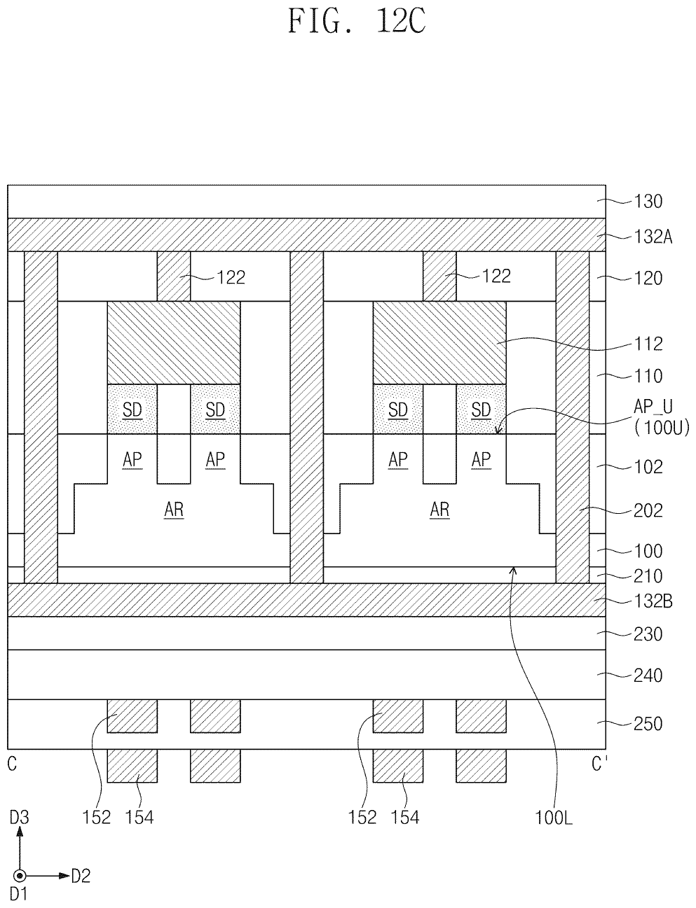

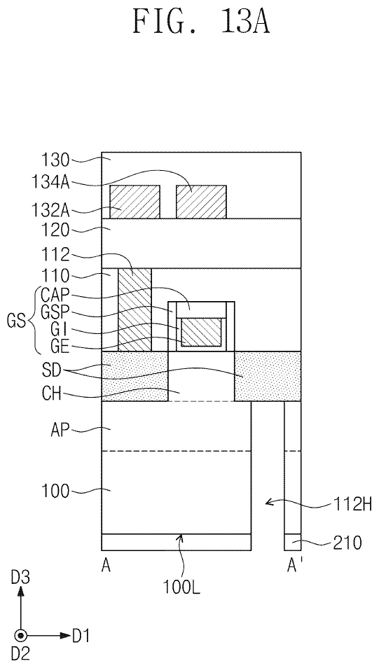

FIG. 11 illustrates a plan view showing a semiconductor device according to some example embodiments. FIGS. 12A, 12B, and 12C illustrate cross-sectional views respectively taken along lines A-A′, B-B′, and C-C′ of FIG. 11. For brevity of description, the following will mainly discuss a difference from the semiconductor device discussed with reference to FIGS. 2, 3A to 3C, 4A, and 4B.

Referring to FIGS. 11 and 12A to 12C, the first source/drain contact 112 may penetrate the first interlayer dielectric layer 110 to come into connection with the first source/drain pattern SD. The first source/drain contact 112 may be disposed on one side of the gate structure GS, and may have a bar shape that extends in the second direction D2. The gate contact 114 may penetrate the first interlayer dielectric layer 110 and the gate capping pattern CAP, and may be connected to the gate electrode GE. The first source/drain contact 112 and the gate contact 114 may have top surfaces substantially coplanar with that of the first interlayer dielectric layer 110. The first source/drain contact 112 and the gate contact 114 may include the same conductive material.

The second interlayer dielectric layer 120 may be disposed on the first interlayer dielectric layer 110, and may cover the top surfaces of the first source/drain contact 112 and the gate contact 114.

The first via contacts 122 may be disposed in the second interlayer dielectric layer 120. Each of the first via contacts 122 may penetrate the second interlayer dielectric layer 120 to come into connection with a corresponding one of the first source/drain contact 112 and the gate contact 114.

The frontside conductive lines 132A and 134A may be disposed on the second interlayer dielectric layer 120. The frontside conductive lines 132A and 134A may include the frontside source line 132A and the frontside word line 134A. The frontside source line 132A may be connected to the first source/drain contact 112 through a corresponding one of the first via contacts 122, and may be electrically connected to the first source/drain pattern SD through the first source/drain contact 112. The frontside word line 134A may be connected to the gate contact 114 through a corresponding one of the first via contacts 112, and may be electrically connected through the gate contact 114 to the gate structure GS (or the gate electrode GE).

The third interlayer dielectric layer 130 may be disposed on the second interlayer dielectric layer 120, and may cover the frontside conductive lines 132A and 134A.

According to some example embodiments, the backside conductive lines 132B and 134B and the first conductive line 136 may be disposed on the bottom surface 100L of the substrate 100. The lower dielectric layer 210 may be interposed between the bottom surface 100L of the substrate 100 and the backside conductive lines 132B and 134B and between the bottom surface 100L of the substrate 100 and the first conductive line 136. The backside conductive lines 132B and 134B and the first conductive line 136 may include the same conductive material, such as metal. The backside conductive lines 132B and 134B may include the backside source line 132B and the backside word line 134B.

The second source/drain contact 112 may be provided to penetrate at least a portion of the substrate 100. The second source/drain contact 112 may penetrate the lower dielectric layer 210 and the substrate 100, and may be connected to the second source/drain pattern SD. The second source/drain contact 112 may be connected to the first conductive line 136. The first conductive line 136 may be electrically connected through the second source/drain contact 112 to the second source/drain pattern SD.

A first lower interlayer dielectric layer 230 may be disposed on the lower dielectric layer 210 and the bottom surface 100L of the substrate 100, and may cover the backside conductive lines 132B and 134B and the first conductive line 136. The first lower interlayer dielectric layer 230 may include, for example, at least one selected from a silicon oxide layer, a silicon nitride layer, a silicon oxynitride layer, and a low-k dielectric layer.

The data storage pattern DS may be disposed on the first lower interlayer dielectric layer 230 and the bottom surface 100L of the substrate 100. The lower electrode contact 138 may be disposed in the first lower interlayer dielectric layer 230, and may be interposed between the data storage pattern DS and the first conductive line 136. The lower electrode contact 138 may penetrate the first lower interlayer dielectric layer 230 to come into connection with the first conductive line 136 and the data storage pattern DS. The lower electrode contact 138 may be connected to the bottom electrode BE of the data storage pattern DS. The data storage pattern DS may be electrically connected through the lower electrode contact 138 to the first conductive line 136. The data storage pattern DS may be electrically connected to the second source/drain pattern SD through the lower electrode contact 138, the first conductive line 136, and the second source/drain contact 112.

A second lower interlayer dielectric layer 240 may be disposed on the first lower interlayer dielectric layer 230 and the bottom surface 100L of the substrate 100, and may cover the data storage pattern DS. The second lower interlayer dielectric layer 240 may include, for example, at least one selected from a silicon oxide layer, a silicon nitride layer, a silicon oxynitride layer, and a low-k dielectric layer.

The first cell conductive line 152 may be disposed on the second lower interlayer dielectric layer 240 and the bottom surface 100L of the substrate 100. The first cell conductive line 152 may be electrically connected to the data storage pattern DS, and may be connected to the top electrode TE of the data storage pattern DS.

A third lower interlayer dielectric layer 250 may be disposed on the second lower interlayer dielectric layer 240 and the bottom surface 100L of the substrate 100, and may cover the first cell conductive line 152. The third lower interlayer dielectric layer 250 may include, for example, at least one selected from a silicon oxide layer, a silicon nitride layer, a silicon oxynitride layer, and a low-k dielectric layer.

The second cell conductive line 154 may be disposed on the third lower interlayer dielectric layer 250 and the bottom surface 100L of the substrate 100. The second via contact 156 may be disposed in the third lower interlayer dielectric layer 250, and may be interposed between the first cell conductive line 152 and the second cell conductive line 154. The first cell conductive line 152 and the second cell conductive line 154 may be electrically connected to each other through the second via contact 156.

According to various example embodiments, the substrate 100 may be provided on its bottom surface 100L with the first conductive line 136, the lower electrode contact 138, the data storage pattern DS, the first and second cell conductive lines 152 and 154, and the second via contact 156. The second source/drain contact 112 may penetrate the lower dielectric layer 210 and the substrate 100, and may be connected to the first conductive line 136 and the second source/drain pattern SD.

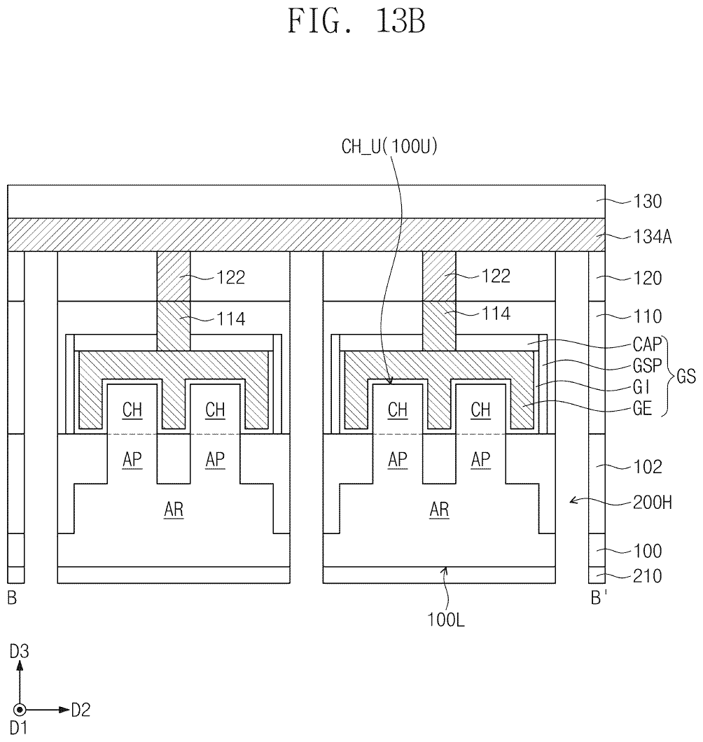

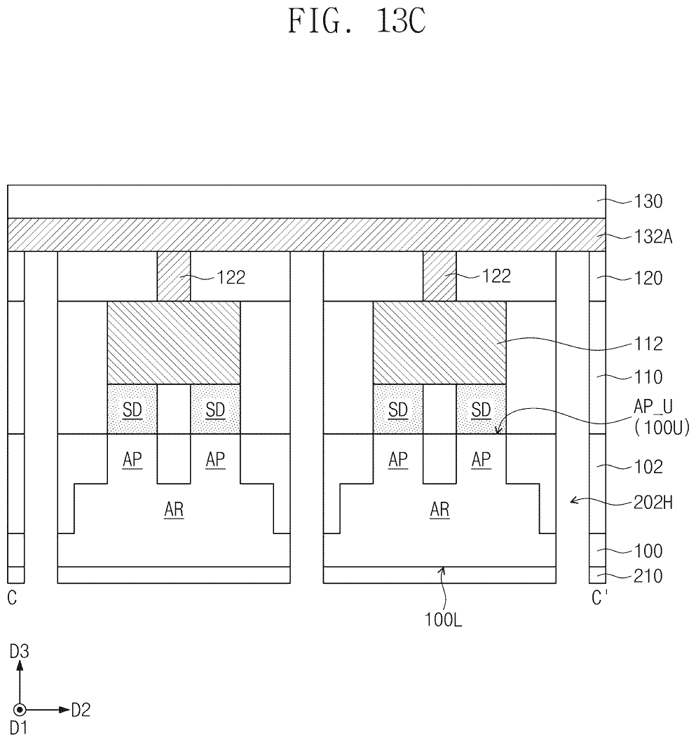

FIGS. 13A, 13B, and 13C illustrate cross-sectional views respectively taken along lines A-A′, B-B′, and C-C′ of FIG. 11, showing a method of fabricating a semiconductor device according to some example embodiments. For brevity of description, the following will mainly discuss a difference from the method of fabricating a semiconductor device discussed with reference to FIGS. 5A to 5C and 6A to 6C.

Referring to FIGS. 11 and 13A to 13C, the first source/drain contact 112 and the gate contact 114 may be formed in the first interlayer dielectric layer 110. The first source/drain contact 112 may penetrate the first interlayer dielectric layer 110 to come into connection with the first source/drain pattern SD, and the gate contact 114 may penetrate the first interlayer dielectric layer 110 and the gate capping pattern CAP to come into connection with the gate electrode GE. The first source/drain contact 112 and the gate contact 114 may be formed by a method substantially the same as that used for forming the source/drain contacts 112 and the gate contact 114 discussed with reference to FIGS. 5A to 5C.

The second interlayer dielectric layer 120 may be formed on the first interlayer dielectric layer 110, and the first via contacts 122 may be formed in the second interlayer dielectric layer 120. Each of the first via contacts 122 may be formed to be connected to a corresponding one of the first source/drain contact 112 and the gate contact 114.

The frontside conductive lines 132A and 134A may be formed on the second interlayer dielectric layer 120. The frontside conductive lines 132A and 134A may be formed by a method substantially the same as that discussed with reference to FIGS. 5A to 5C. The frontside conductive lines 132A and 134A may include the frontside source line 132A and the frontside word line 134A. The frontside source line 132A may be connected to the first source/drain contact 112 through a corresponding one of the first via contacts 122, and may be electrically connected through the first source/drain contact 112 to the first source/drain pattern SD. The frontside word line 134A may be connected to the gate contact 114 through a corresponding one of the first via contacts 112, and may be electrically connected through the gate contact 114 to the gate structure GS (or the gate electrode GE).

The third interlayer dielectric layer 130 may be formed on the second interlayer dielectric layer 120, and may cover the frontside conductive lines 132A and 134A.

The lower dielectric layer 210 may be formed on the bottom surface 100L of the substrate 100. The through via holes 200H and 202H and a second source/drain contact hole 112H may be formed to penetrate the lower dielectric layer 210 and the substrate 100. The second source/drain contact hole 112H may be formed to penetrate the lower dielectric layer 210 and the substrate 100 and to expose a bottom surface of the second source/drain pattern SD.

Referring back to FIGS. 11 and 12A to 12C, the through vias 200 and 202 may be correspondingly formed in the through via holes 200H and 202H, and the second source/drain contact 112 may be formed in the second source/drain contact hole 112H. The formation of the through vias 200 and 202 and the second source/drain contact 112 may include, for example, forming on the bottom surface 100L of the substrate 100 a conductive layer to fill the through via holes 200H and 202H and the second source/drain contact hole 112H, and planarizing the conductive layer until the lower dielectric layer 210 is exposed.

The backside conductive lines 132B and 134B and the first conductive line 136 may be formed on the lower dielectric layer 210 and the bottom surface 100L of the substrate 100. The formation of the backside conductive lines 132B and 134B and the first conductive line 136 may include, for example, forming a backside conductive layer on the lower dielectric layer 210 and patterning the backside conductive layer.

A first lower interlayer dielectric layer 230 may be formed on the lower dielectric layer 210 and the bottom surface 100L of the substrate 100, thereby covering the backside conductive lines 132B and 134B and the first conductive line 136.

The data storage pattern DS may be formed on the first lower interlayer dielectric layer 230 and the bottom surface 100L of the substrate 100. The data storage pattern DS may be formed by a method substantially the same as that discussed with reference to FIGS. 5A to 5C. A second lower interlayer dielectric layer 240 may be formed on the first lower interlayer dielectric layer 230 and the bottom surface 100L of the substrate 100, thereby covering the data storage pattern DS.

The first cell conductive line 152 may be formed on the second lower interlayer dielectric layer 240 and the bottom surface 100L of the substrate 100. A third lower interlayer dielectric layer 250 may be formed on the second lower interlayer dielectric layer 240 and the bottom surface 100L of the substrate 100, thereby covering the first cell conductive line 152.

The second cell conductive line 154 may be formed on the third lower interlayer dielectric layer 250 and the bottom surface 100L of the substrate 100. The second via contact 156 may be formed in the third lower interlayer dielectric layer 250, thereby being interposed between the first cell conductive line 152 and the second cell conductive line 154. The first cell conductive line 152 and the second cell conductive line 154 may be electrically connected to each other through the second via contact 156.

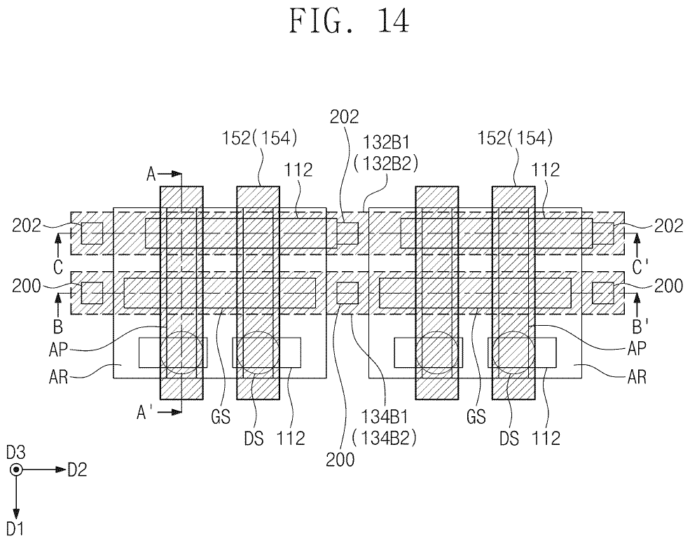

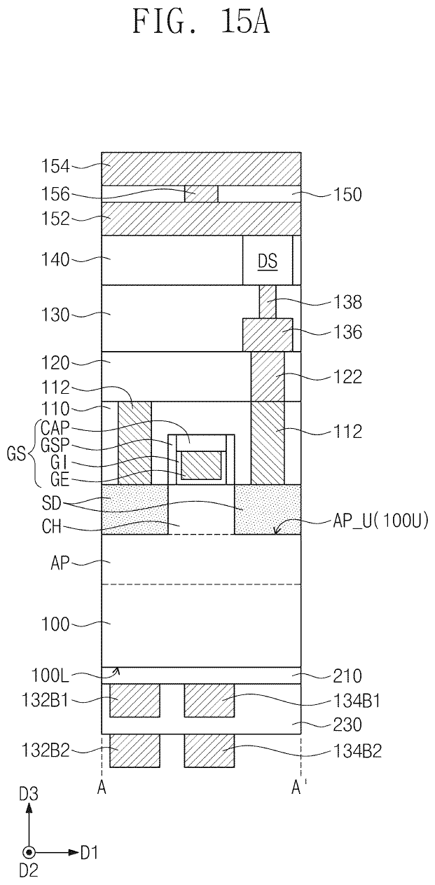

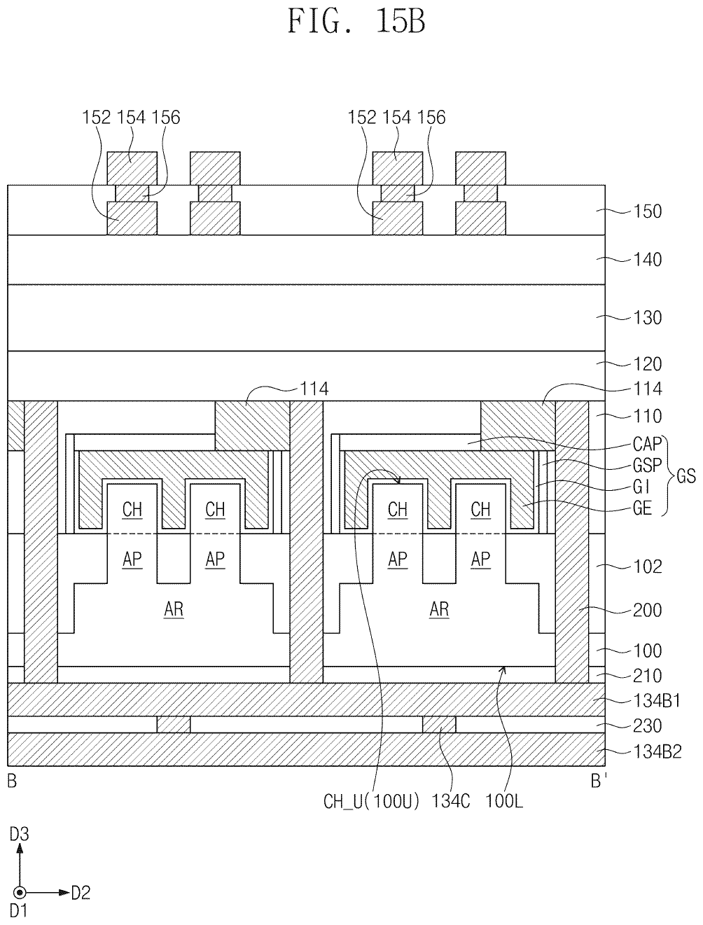

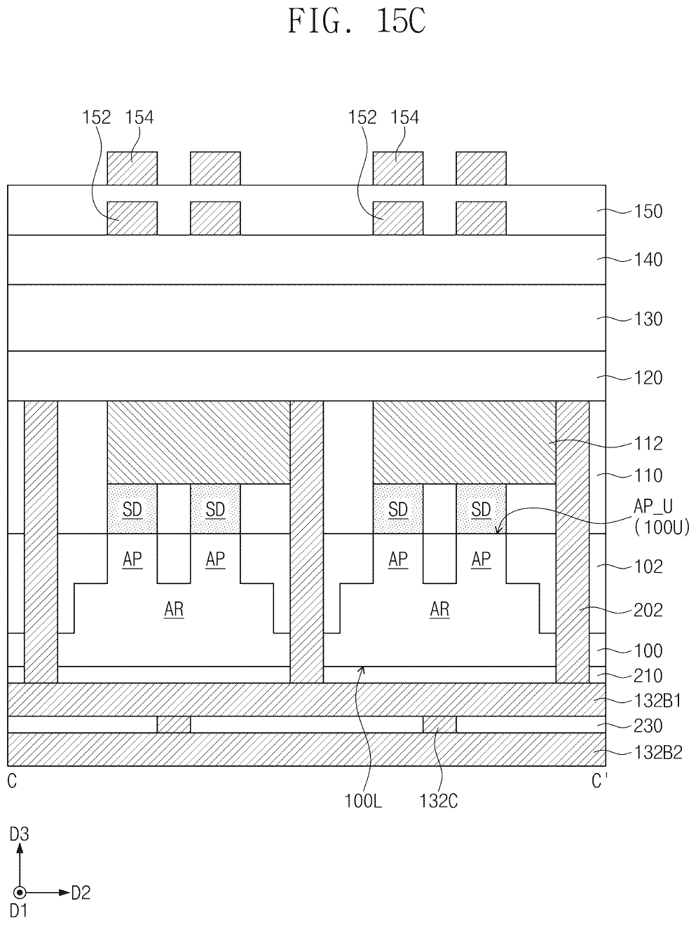

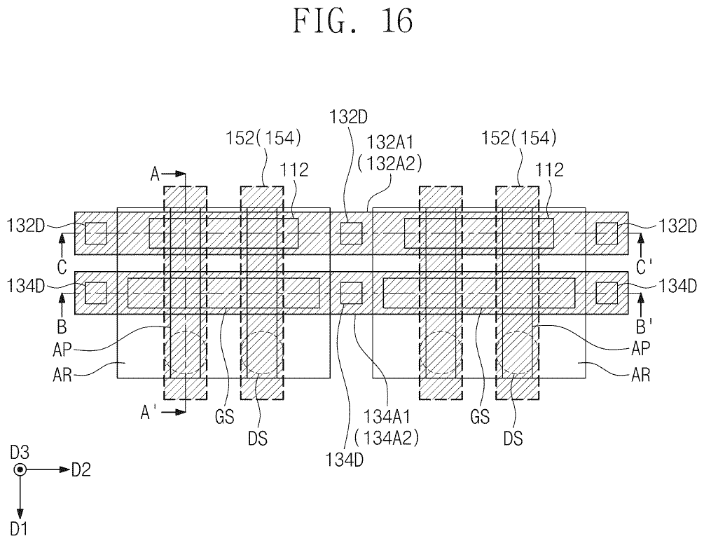

FIG. 14 illustrates a plan view showing a semiconductor device according to some example embodiments. FIGS. 15A, 15B, and 15C illustrate cross-sectional views respectively taken along lines A-A′, B-B′, and C-C′ of FIG. 14. For brevity of description, the following will mainly discuss a difference from the semiconductor device discussed with reference to FIGS. 2, 3A to 3C, 4A, and 4B.

Referring to FIGS. 14 and 15A to 15C, the first via contacts 122 may be disposed in the second interlayer dielectric layer 120. Each of the first via contacts 122 may penetrate the second interlayer dielectric layer 120 to come into connection with the second source/drain contact 112. According to some example embodiments, the first via contacts 122 may not be provided on any of the first source/drain contact 112 and the gate contact 114, and may not be connected to any of the first source/drain contact 112 and the gate contact 114.

According to some example embodiments, the frontside conductive lines 132A and 134A may be omitted. The first conductive line 136 may be disposed on the second interlayer dielectric layer 120. The first conductive line 136 may be connected to the second source/drain contact 112 through a corresponding one of the first via contacts 122, and may be electrically connected through the second source/drain contact 112 to the second source/drain pattern SD. The third interlayer dielectric layer 130 may be disposed on the second interlayer dielectric layer 120, and may cover the first conductive line 136.

According to some example embodiments, first backside conductive lines 132B1 and 134B1 may be disposed on the bottom surface 100L of the substrate 100, and the lower dielectric layer 210 may be interposed between the bottom surface 100L of the substrate 100 and the first backside conductive lines 132B1 and 134B1. The first backside conductive lines 132B1 and 134B1 may include a first backside source line 132B1 and a first backside word line 134B1. The first backside source line 132B1 and the first backside word line 134B1 may extend in the second direction D2 and may be spaced apart from each other in the first direction D1.

The through vias 200 and 202 may be provided to penetrate at least a portion of the substrate 100. Each of the through vias 200 and 202 may penetrate the lower dielectric layer 210, the substrate 100, the device isolation layer 102, and the first interlayer dielectric layer 110, and may be connected to a corresponding one of the first backside conductive lines 132B1 and 134B1. The through vias 200 and 202 may include first through vias 200 connected to the first backside word line 134B1 and second through vias 202 connected to the first backside source line 132B1.

Each of the first through vias 200 may be connected to a lateral surface of the gate contact 114. For example, a lateral surface of each of the first through vias 200 may be in contact with the lateral surface of the gate contact 114. The gate contact 114 may not be connected to the first via contacts 122. In this case, the first backside word line 134B1 may be electrically connected to the gate structure GS (or the gate electrode GE) through the first through vias 200 and the gate contact 114.

Each of the second through vias 202 may be connected to a lateral surface of the first source/drain contact 112. For example, the lateral surface of each of the second through vias 202 may be in contact with that of the first source/drain contact 112. The first source/drain contact 112 may not be connected to the first via contacts 122. In this case, the first backside source line 132B1 may be electrically connected to the first source/drain pattern SD through the second through vias 202 and the first source/drain contact 112.

According to some example embodiments, a first lower interlayer dielectric layer 230 may be disposed on the lower dielectric layer 210 and the bottom surface 100L of the substrate 100, and may cover the first backside conductive lines 132B1 and 134B1. The first lower interlayer dielectric layer 230 may include, for example, at least one selected from a silicon oxide layer, a silicon nitride layer, a silicon oxynitride layer, and a low-k dielectric layer.

Second backside conductive lines 132B2 and 134B2 may be disposed on the first lower interlayer dielectric layer 230 and the bottom surface 100L of the substrate 100. The second backside conductive lines 132B2 and 134B2 may include a second backside source line 132B2 and a second backside word line 134B2. The second backside source line 132B2 and the second backside word line 134B2 may extend in the second direction D2 and may be spaced apart from each other in the first direction D1. The second backside source line 132B2 may overlap vertically (e.g., in the third direction D3) with the first backside source line 132B1, and the second backside word line 134B2 may overlap vertically (e.g., in the third direction D3) with the first backside word line 134B1.

First backside contacts 132C may be disposed in the first lower interlayer dielectric layer 230, and may be placed between the first backside source line 132B1 and the second backside source line 132B2. The first backside contacts 132C may be spaced apart from each other in the second direction D2 between the first backside source line 132B1 and the second backside source line 132B2. The first backside source line 132B1 and the second backside source line 132B2 may be connected to each other through the first backside contacts 132C, and may be electrically connected to the first source/drain pattern SD through the second through vias 202 and the first source/drain contact 112. According to some example embodiments, the first backside source line 132B1, the second backside source line 132B2, and the first backside contacts 132C may constitute a source line (see the source line SL of FIG. 1).

Second backside contacts 134C may be disposed in the first lower interlayer dielectric layer 230, and may be placed between the first backside word line 134B1 and the second backside word line 134B2. The second backside contacts 134C may be spaced apart from each other in the second direction D2 between the first backside word line 134B1 and the second backside word line 134B2. The first backside word line 134B1 and the second backside word line 134B2 may be connected to each other through the second backside contacts 134C, and may be electrically connected to the gate structure GS (or the gate electrode GE) through the first through vias 200 and the gate contact 114. According to some example embodiments, the first backside word line 134B1, the second backside word line 134B2, and the second backside contacts 134C may constitute a word line (see the word line WL of FIG. 1).

According to various example embodiments, the substrate 100 may be provided on its top surface 100U with a transistor including the gate structure GS, the channel pattern CH, and the source/drain patterns SD. A word line connected to a gate terminal (or the gate electrode GE) of the transistor may include the first backside word line 134B1, the second backside word line 134B2, and the second backside contacts 134C that are disposed on the bottom surface 100L of the substrate 100. As the word line includes the first backside word line 134B1 and the second backside word line 134B2 that are connected in parallel to each other, the word line may decrease in resistance. In addition, a source line connected to a source terminal (e.g., the first source/drain pattern SD) of the transistor may include the first backside source line 132B1, the second backside source line 132B2, and the first backside contacts 132C that are disposed on the bottom surface 100L of the substrate 100. As the source line includes the first backside source line 132B1 and the second backside source line 132B2 that are connected in parallel to each other, the source line may decrease in resistance. It therefore may be possible to provide a semiconductor device with improved electrical properties.

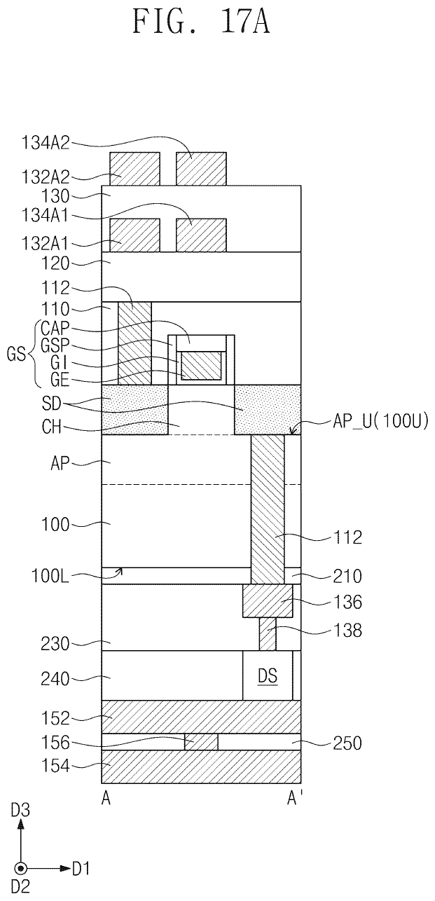

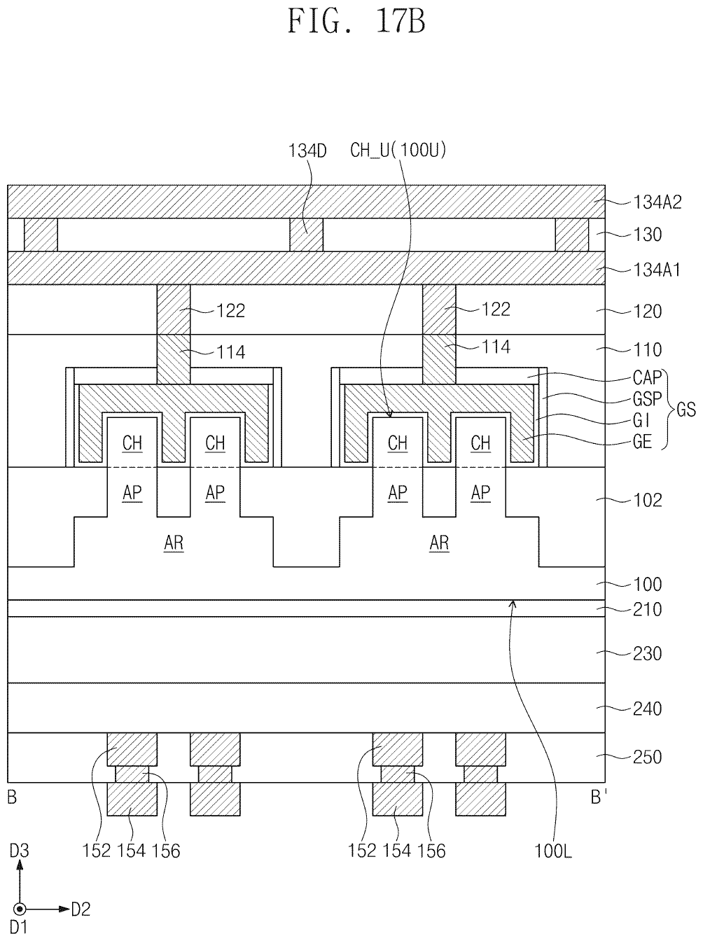

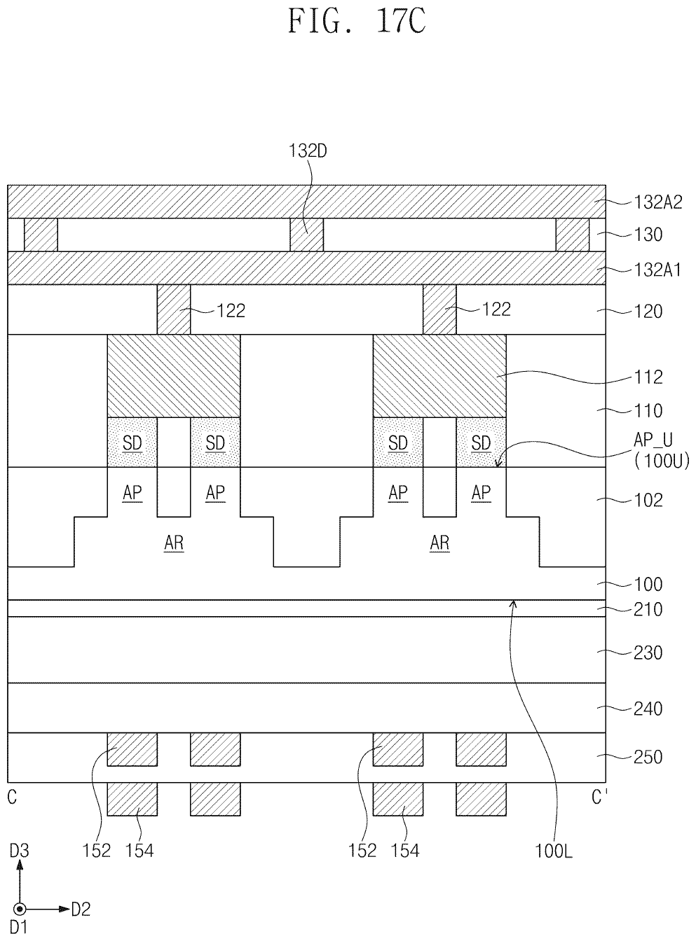

FIG. 16 illustrates a plan view showing a semiconductor device according to some example embodiments. FIGS. 17A, 17B, and 17C illustrate cross-sectional views respectively taken along lines A-A′, B-B′, and C-C′ of FIG. 16. For brevity of description, the following will mainly discuss a difference from the semiconductor device discussed with reference to FIGS. 2, 3A to 3C, 4A, and 4B.

Referring to FIGS. 16 and 17A to 17C, the first source/drain contact 112 may penetrate the first interlayer dielectric layer 110 to come into connection with the first source/drain pattern SD. The first source/drain contact 112 may be disposed on one side of the gate structure GS, and may have a bar shape that extends in the second direction D2. The gate contact 114 may penetrate the first interlayer dielectric layer 110 and the gate capping pattern CAP, and may be connected to the gate electrode GE. The first source/drain contact 112 and the gate contact 114 may have top surfaces substantially coplanar with that of the first interlayer dielectric layer 110. The first source/drain contact 112 and the gate contact 114 may include the same conductive material.

The second interlayer dielectric layer 120 may be disposed on the first interlayer dielectric layer 110, and may cover the top surfaces of the first source/drain contact 112 and the gate contact 114.

The first via contacts 122 may be disposed in the second interlayer dielectric layer 120. Each of the first via contacts 122 may penetrate the second interlayer dielectric layer 120 to come into connection with a corresponding one of the first source/drain contact 112 and the gate contact 114.

First frontside conductive lines 132A1 and 134A1 may be disposed on the second interlayer dielectric layer 120. The first frontside conductive lines 132A1 and 134A1 may include a first frontside source line 132A1 and a first frontside word line 134A1. The first frontside source line 132A1 and the first frontside word line 134A1 may extend in the second direction D2 and may be spaced apart from each other in the first direction D1. The first frontside source line 132A1 may be connected to the first source/drain contact 112 through a corresponding one of the first via contacts 122, and may be electrically connected through the first source/drain contact 112 to the first source/drain pattern SD. The first frontside word line 134A1 may be connected to the gate contact 114 through a corresponding one of the first via contacts 122, and may be electrically connected through the gate contact 114 to the gate structure GS (or the gate electrode GE).

The third interlayer dielectric layer 130 may be disposed on the second interlayer dielectric layer 120, and may cover the first frontside conductive lines 132A1 and 134A1.

Second frontside conductive lines 132A2 and 134A2 may be disposed on the third interlayer dielectric layer 130. The second frontside conductive lines 132A2 and 134A2 may include a second frontside source line 132A2 and a second frontside word line 134A2. The second frontside source line 132A2 and the second frontside word line 134A2 may extend in the second direction D2 and may be spaced apart from each other in the first direction D1. The second frontside source line 132A2 may overlap vertically (e.g., in the third direction D3) with the first frontside source line 132A1, and the second frontside word line 134A2 may overlap vertically (e.g., in the third direction D3) with the first frontside word line 134A1.

First frontside contacts 132D may be disposed in the third interlayer dielectric layer 130, and may be placed between the first frontside source line 132A1 and the second frontside source line 132A2. The first frontside contacts 132D may be spaced apart from each other in the second direction D2 between the first frontside source line 132A1 and the second frontside source line 132A2. The first frontside source line 132A1 and the second frontside source line 132A2 may be connected to each other through the first frontside contacts 132D, and may be electrically connected to the first source/drain pattern SD through a corresponding first via contact 122 and the first source/drain contact 112. According to some example embodiments, the first frontside source line 132A1, the second frontside source line 132A2, and the first frontside contacts 132D may constitute a source line (see the source line SL of FIG. 1).

Second frontside contacts 134D may be disposed in the third interlayer dielectric layer 130, and may be placed between the first frontside word line 134A1 and the second frontside word line 134A2. The second frontside contacts 134D may be spaced apart from each other in the second direction D2 between the first frontside word line 134A1 and the second frontside word line 134A2. They first frontside word line 134A1 and the second frontside word line 134A2 may be connected to each other through the second frontside contacts 134D, and may be electrically connected to the gate structure GS (or the gate electrode GE) through a corresponding first via contact 122 and the gate contact 114. According to some example embodiments, the first frontside word line 134A1, the second frontside word line 134A2, and the second frontside contacts 134D may constitute a word line (see the word line WL of FIG. 1).

According to some example embodiments, the first conductive line 136 may be disposed on the bottom surface 100L of the substrate 100. The lower dielectric layer 210 may be interposed between the first conductive line 136 and the bottom surface 100L of the substrate 100. The second source/drain contact 112 may be provided to penetrate at least a portion of the substrate 100. The second source/drain contact 112 may penetrate the lower dielectric layer 210 and the substrate 100, and may be connected to the second source/drain pattern SD. The second source/drain contact 112 may be connected to the first conductive line 136. The first conductive line 136 may be electrically connected through the second source/drain contact 112 to the second source/drain pattern SD.

A first lower interlayer dielectric layer 230 may be disposed on the lower dielectric layer 210 and the bottom surface 100L of the substrate 100, and may cover the first conductive line 136. According to some example embodiments, the backside conductive lines 132B and 134B may be omitted. The first lower interlayer dielectric layer 230 may include, for example, at least one selected from a silicon oxide layer, a silicon nitride layer, a silicon oxynitride layer, and a low-k dielectric layer.

The data storage pattern DS may be disposed on the first lower interlayer dielectric layer 230 and the bottom surface 100L of the substrate 100. The lower electrode contact 138 may be disposed in the first lower interlayer dielectric layer 230, and may be interposed between the data storage pattern DS and the first conductive line 136. The lower electrode contact 138 may penetrate the first lower interlayer dielectric layer 230 to come into connection with the first conductive line 136 and the data storage pattern DS. The lower electrode contact 138 may be connected to the bottom electrode BE of the data storage pattern DS. The data storage pattern DS may be electrically connected through the lower electrode contact 138 to the first conductive line 136. The data storage pattern DS may be electrically connected to the second source/drain pattern SD through the lower electrode contact 138, the first conductive line 136, and the second source/drain contact 112.

A second lower interlayer dielectric layer 240 may be disposed on the first lower interlayer dielectric layer 230 and the bottom surface 100L of the substrate 100, and may cover the data storage pattern DS. The second lower interlayer dielectric layer 240 may include, for example, at least one selected from a silicon oxide layer, a silicon nitride layer, a silicon oxynitride layer, and a low-k dielectric layer.

The first cell conductive line 152 may be disposed on the second lower interlayer dielectric layer 240 and the bottom surface 100L of the substrate 100. The first cell conductive line 152 may be electrically connected to the data storage pattern DS, and may be connected to the top electrode TE of the data storage pattern DS.

A third lower interlayer dielectric layer 250 may be disposed on the second lower interlayer dielectric layer 240 and the bottom surface 100L of the substrate 100, and may cover the first cell conductive line 152. The third lower interlayer dielectric layer 250 may include, for example, at least one selected from a silicon oxide layer, a silicon nitride layer, a silicon oxynitride layer, and a low-k dielectric layer.

The second cell conductive line 154 may be disposed on the third lower interlayer dielectric layer 250 and the bottom surface 100L of the substrate 100. The second via contact 156 may be disposed in the third lower interlayer dielectric layer 250, and may be interposed between the first cell conductive line 152 and the second cell conductive line 154. The first cell conductive line 152 and the second cell conductive line 154 may be electrically connected to each other through the second via contact 156.

According to various example embodiments, the substrate 100 may be provided on its top surface 100U with a transistor including the gate structure GS, the channel pattern CH, and the source/drain patterns SD, and the data storage pattern DS may be disposed on the bottom surface 100L of the substrate 100. A semiconductor device may easily have an advantage of high integration.

Alternatively or additionally, a word line connected to a gate terminal (or the gate electrode GE) of the transistor may include the first frontside word line 134A1, the second frontside word line 134A2, and the second frontside contacts 134D that are disposed on the top surface 100U of the substrate 100. As the word line includes the first frontside word line 134A1 and the second frontside word line 134A2 that are connected in parallel to each other, the word line may decrease in resistance. Moreover, a source line connected to a source terminal (or the first source/drain pattern SD) of the transistor may include the first frontside source line 132A1, the second frontside source line 132A2, and the first frontside contacts 132D that are disposed on the top surface 100U of the substrate 100. As the source line includes the first frontside source line 132A1 and the second frontside source line 132A2 that are connected in parallel to each other, the source line may decrease in resistance. It therefore may be possible to provide a semiconductor device with improved electrical properties.

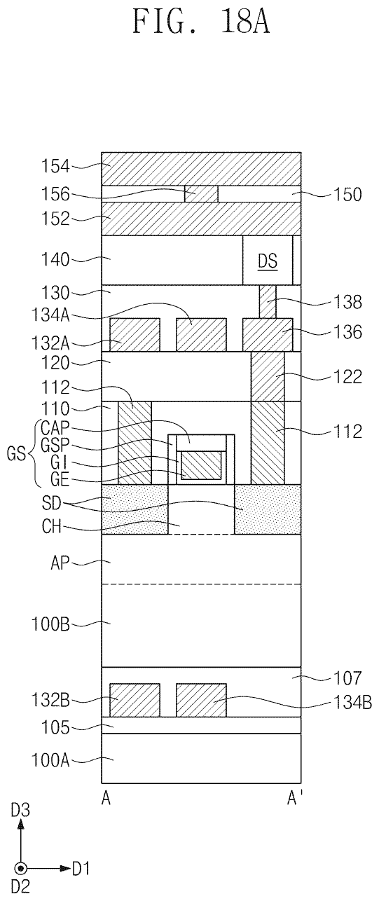

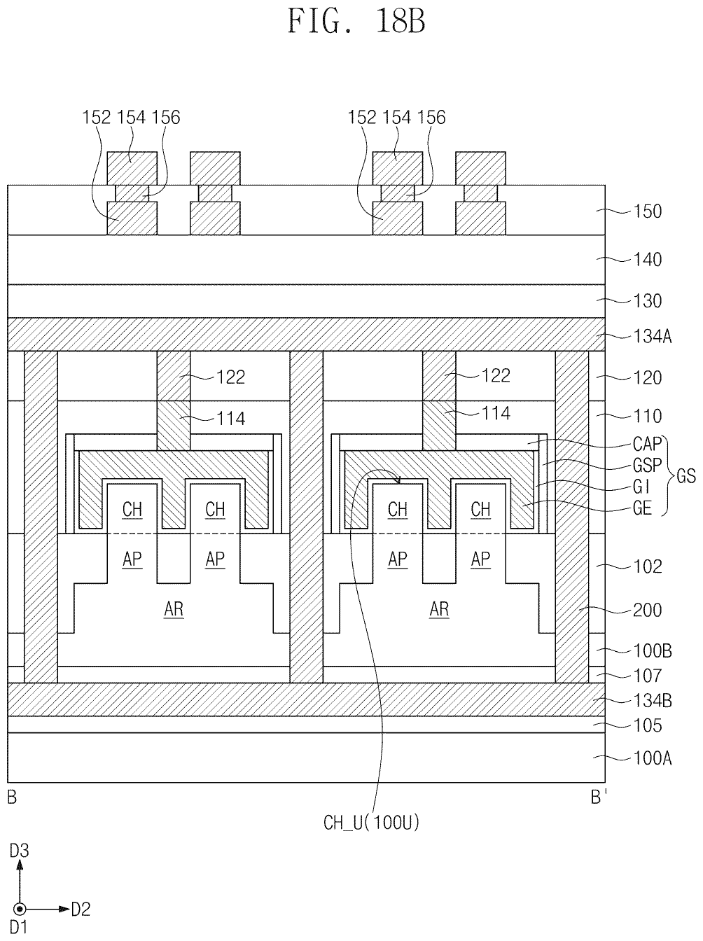

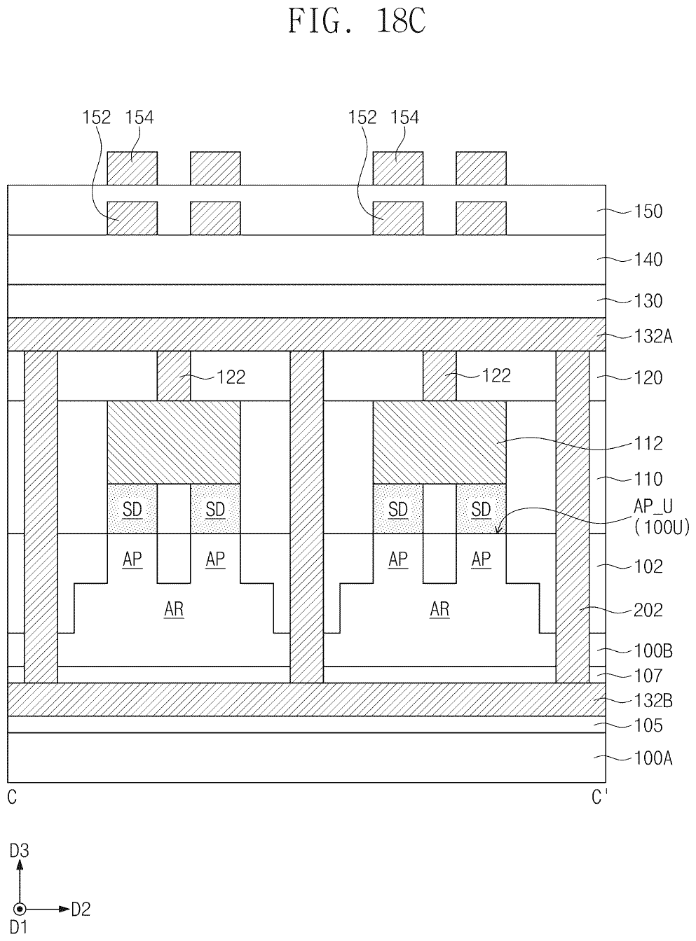

FIGS. 18A, 18B, and 18C illustrate cross-sectional views respectively taken along lines A-A′, B-B′, and C-C′ of FIG. 2, showing a semiconductor device according to some example embodiments. For brevity of description, the following will mainly discuss a difference from the semiconductor device discussed with reference to FIGS. 2, 3A to 3C, 4A, and 4B.

Referring to FIGS. 2 and 18A to 18C, a first buried dielectric layer 105 may be disposed in a lower substrate 100A, and the backside conductive lines 132B and 134B may be disposed on the first buried dielectric layer 105. The first buried dielectric layer 105 is provided therein with a second buried dielectric layer 107 that covers the backside conductive lines 132B and 134B. An upper substrate 100B may be disposed on the second buried dielectric layer 107.

The lower substrate 100A may be or may include one or more of a semiconductor substrate, for example, a silicon substrate, a germanium substrate, or a silicon-germanium substrate. The first and second buried dielectric layers 105 and 107 may include at least one selected from a silicon oxide layer, a silicon nitride layer, and a silicon oxynitride layer. The upper substrate 100B may be substantially the same as the substrate 100 discussed with reference to FIGS. 2 and 3A to 3C. The first and second buried dielectric layers 105 and 107 may be called a buried dielectric layer. The backside conductive lines 132B and 134B may be buried in the buried dielectric layer 105 and 107 between the lower substrate 100A and the upper substrate 100B.

Each of the through vias 200 and 202 may penetrate an upper portion of the second buried dielectric layer 107, the upper substrate 100B, the device isolation layer 102, the first interlayer dielectric layer 110, and the second interlayer dielectric layer 120, and may be connected to a corresponding one of the backside conductive lines 132B and 134B and a corresponding one of the frontside conductive lines 132A and 134A.

Except for the mentioned above, a semiconductor device according to various example embodiments may be substantially the same as the semiconductor device discussed with reference to FIGS. 3A to 3C, 4A, and 4B.

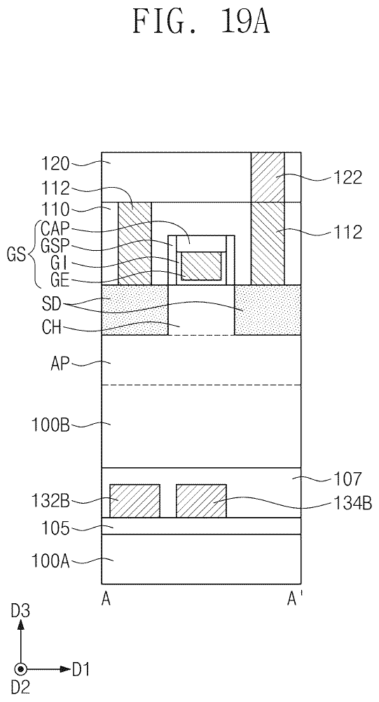

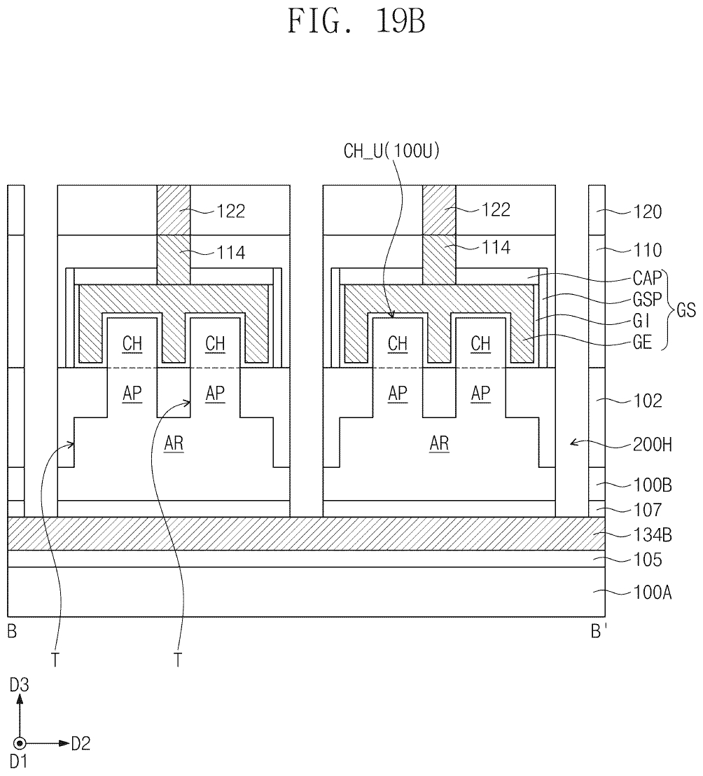

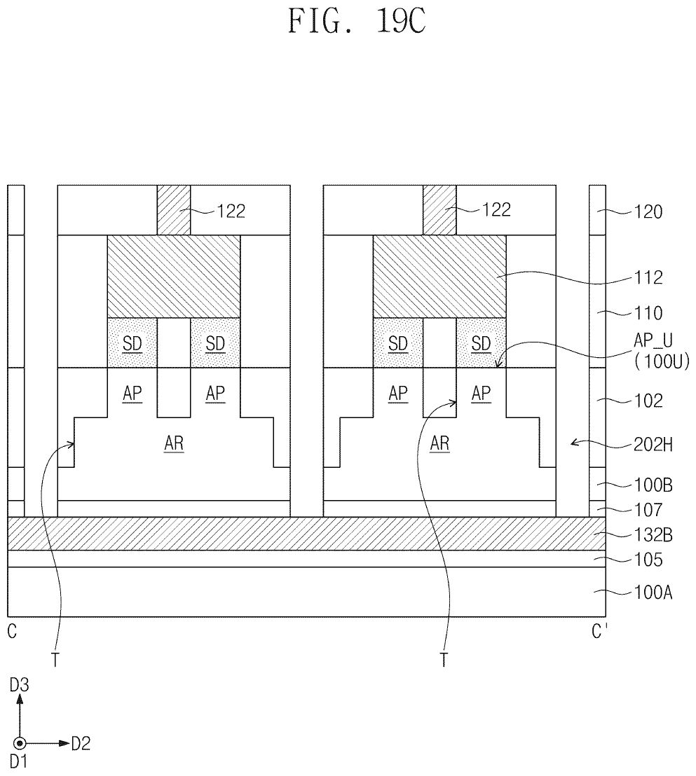

FIGS. 19A, 19B, and 19C illustrate cross-sectional views respectively taken along lines A-A′, B-B′, and C-C′ of FIG. 2, showing a method of fabricating a semiconductor device according to some example embodiments. For brevity of description, the following will mainly discuss a difference from the method of fabricating a semiconductor device discussed with reference to FIGS. 5A to 5C and 6A to 6C.

Referring to FIGS. 2 and 19A to 19C, a first buried dielectric layer 105 may be formed on a lower substrate 100A, and the backside conductive lines 132B and 134B may be formed on the first buried dielectric layer 105. A second buried dielectric layer 107 may be formed on the first buried dielectric layer 105 to cover the backside conductive lines 132B and 134B. An upper substrate 100B may be formed on the second buried dielectric layer 107. The formation of the upper substrate 100B may include, for example, depositing on the second buried dielectric layer 107 one of a silicon layer, a germanium layer, and a silicon-germanium layer.

The trenches T may be formed on an upper portion of the upper substrate 100B to define the active regions AR and the active patterns AP. The device isolation layer 102 may be formed to fill the trenches T, and may be recessed to expose an upper portion of each active pattern AP. The sacrificial gate structure may be formed to run across the active patterns AP. The sacrificial gate structure may include the sacrificial gate pattern that runs across the active patterns AP, and may also include the gate spacers GSP on lateral surfaces of the sacrificial gate pattern. The source/drain patterns SD may be formed on the active patterns AP on opposite sides of the sacrificial gate structure.

A lower portion of the first interlayer dielectric layer 110 may be formed to cover the sacrificial gate structure and the source/drain patterns SD, and the gate structure GS may be formed in the lower portion of the first interlayer dielectric layer 110. The formation of the gate structure GS may include, for example, removing the sacrificial gate pattern to form an empty space that exposes the channel pattern CH between the gate spacers GSP, and forming the gate dielectric pattern GI, the gate electrode GE, and the gate capping pattern CAP in the empty space. The gate structure GS may include the gate electrode GE that runs across the active patterns AP, the gate dielectric pattern GI between the gate electrode GE and the channel pattern CH, the gate spacers GSP on lateral surfaces of the gate electrode GE, and the gate capping pattern CAP on a top surface of the gate electrode GE. An upper portion of the first interlayer dielectric layer 110 may be formed to cover the gate structure GS.

The source/drain contacts 112 and the gate contact 114 may be formed in the first interlayer dielectric layer 110. The second interlayer dielectric layer 120 may be formed on the first interlayer dielectric layer 110, and the first via contacts 122 may be formed in the second interlayer dielectric layer 120.

According to some example embodiments, the through holes 200H and 202H may be formed to penetrate the second interlayer dielectric layer 120, the first interlayer dielectric layer 110, the device isolation layer 102, and the upper substrate 100B, and to penetrate a portion of the second buried dielectric layer 107 to expose top surfaces of the backside conductive lines 132B and 134B. The through via holes 200H and 202H may include the first through via holes 200H that expose a top surface of the backside word line 134B among the backside conductive lines 132B and 134B, and may also include the second through via holes 202H that expose a top surface of the backside source line 132B among the backside conductive lines 132B and 134B.

Referring back to FIGS. 2 and 18A to 18C, the through vias 200 and 202 may be respectively formed in the through via holes 200H and 202H. The formation of the through vias 200 and 202 may include, for example, forming on the second interlayer dielectric layer 120 a conductive layer to fill the through via holes 200H and 202H, and planarizing the conductive layer until the second interlayer dielectric layer 120 is exposed. The through vias 200 and 202 may include the first through vias 200 that are spaced apart from each other in the second direction D2 along a top surface of the backside word line 134B, and may also include the second through vias 202 that are spaced apart from each other in the second direction D2 along a top surface of the backside source line 132B.

Afterwards, the frontside conductive lines 132A and 134A and the first conductive line 136 may be formed on the second interlayer dielectric layer 120. The frontside conductive lines 132A and 134A may include the frontside source line 132A and the frontside word line 134A. The backside source line 132B may overlap vertically (e.g., in the third direction D3) with the frontside source line 132A, and the backside word line 134B may overlap vertically (e.g., in the third direction D3) with the frontside word line 134A. The backside word line 134B may be connected to the first through vias 200, and may be electrically connected through the first through vias 200 to the frontside word line 134A. The backside source line 132B may be connected to the second through vias 202, and may be electrically connected through the second through vias 202 to the frontside source line 132A.

Except for the mentioned above, a semiconductor device according to various example embodiments may be substantially the same as the semiconductor device discussed with reference to FIGS. 5A to 5C and 6A to 6C.

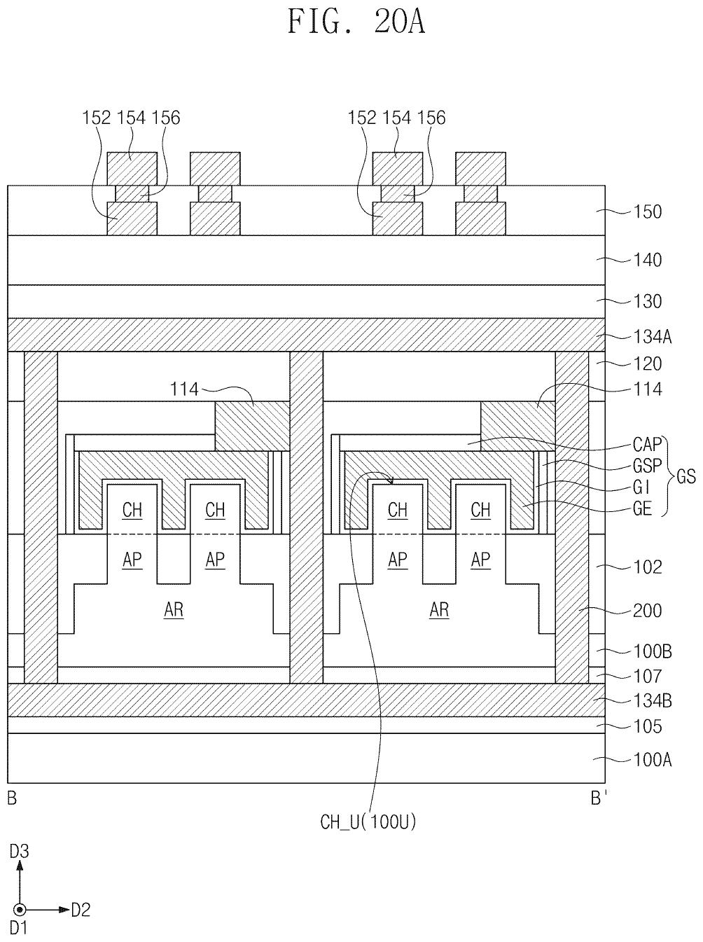

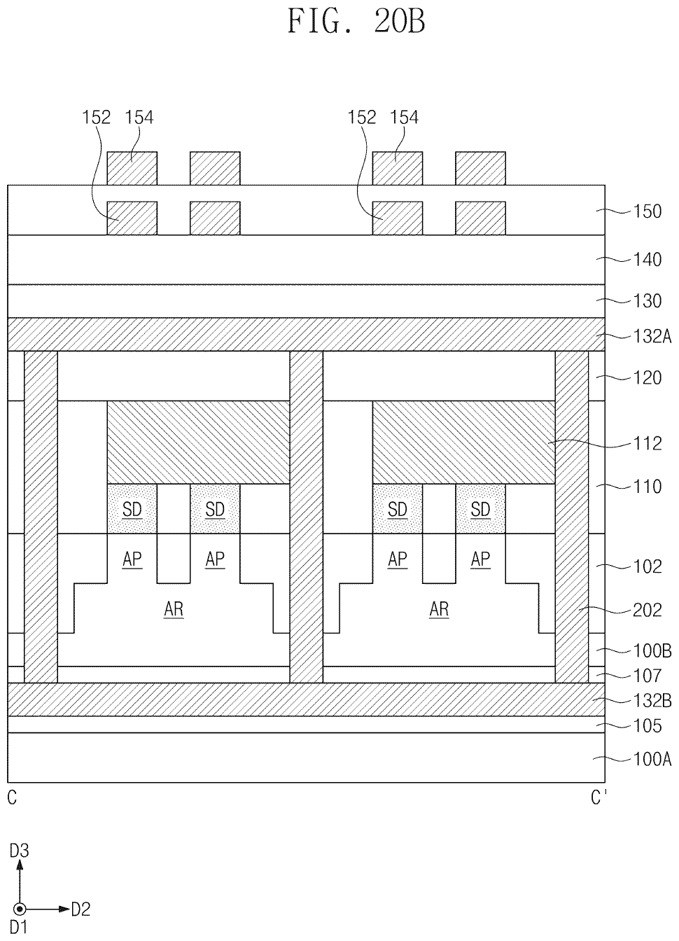

FIGS. 20A and 20B illustrate cross-sectional views respectively taken along lines B-B′ and C-C′ of FIG. 7, showing a semiconductor device according to some example embodiments. For brevity of description, the following will mainly discuss a difference from the semiconductor device discussed with reference to FIGS. 7, 8A, and 8B.

Referring to FIGS. 7, 20A, and 20B, a first buried dielectric layer 105 may be disposed on a lower substrate 100A, and the backside conductive lines 132B and 134B may be disposed on the first buried dielectric layer 105. A second buried dielectric layer 107 may be disposed on the first buried dielectric layer 105, and may cover the backside conductive lines 132B and 134B. An upper substrate 100B may be disposed on the second buried dielectric layer 107. The upper substrate 100B may be substantially the same as the substrate 100 discussed with reference to FIGS. 2 and 3A to 3C. The first and second buried dielectric layers 105 and 107 may be called a buried dielectric layer. The backside conductive lines 132B and 134B may be buried in the buried dielectric layer 105 and 107 between the lower substrate 100A and the upper substrate 100B.

Each of the through vias 200 and 202 may penetrate an upper portion of the second buried dielectric layer 107, the upper substrate 100B, the device isolation layer 102, the first interlayer dielectric layer 110, and the second interlayer dielectric layer 120, and may be connected to a corresponding one of the backside conductive lines 132B and 134B and a corresponding one of the frontside conductive lines 132A and 134A.

Except for the mentioned above, a semiconductor device according to various example embodiments may be substantially the same as the semiconductor device discussed with reference to FIGS. 7, 8A, and 8B.

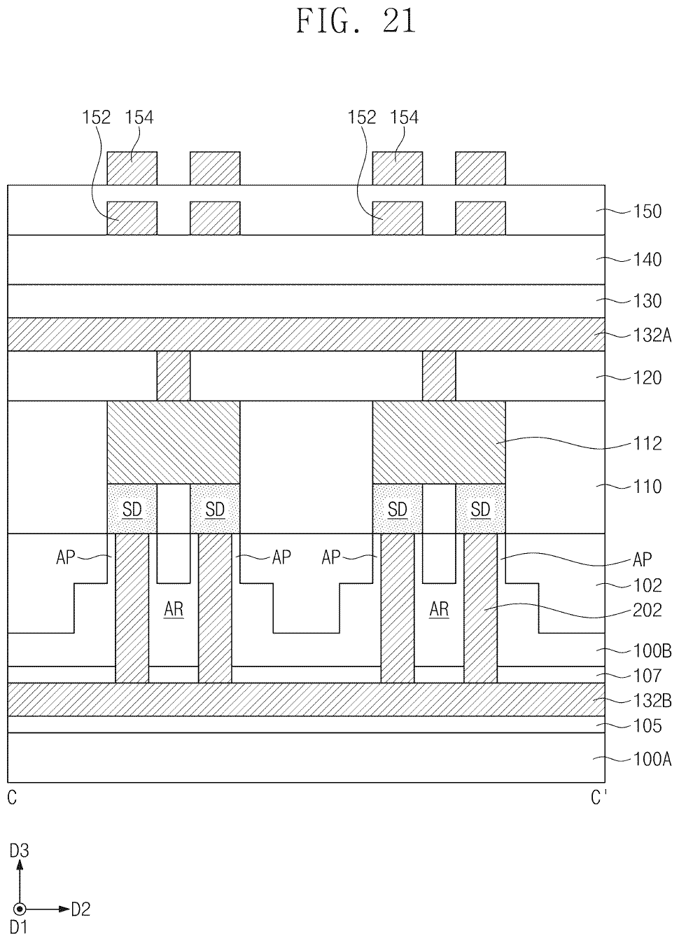

FIG. 21 illustrates a cross-sectional view taken along line C-C′ of FIG. 9, showing a semiconductor device according to some example embodiments. For brevity of description, a difference from the semiconductor device discussed with reference to FIGS. 9 and 10 will be chiefly explained below.

Referring to FIGS. 9 and 21, a first buried dielectric layer 105 may be disposed on a lower substrate 100A, and the backside conductive lines 132B and 134B may be disposed on the first buried dielectric layer 105. A second buried dielectric layer 107 may be disposed on the first buried dielectric layer 105, and may cover the backside conductive lines 132B and 134B. An upper substrate 100B may be disposed on the second buried dielectric layer 107. The upper substrate 100B may be substantially the same as the substrate 100 discussed with reference to FIGS. 2 and 3A to 3C. The first and second buried dielectric layers 105 and 107 may be called a buried dielectric layer. The backside conductive lines 132B and 134B may be buried in the buried dielectric layer 105 and 107 between the lower substrate 100A and the upper substrate 100B.

The second through vias 202 may penetrate the upper substrate 100B, and may also penetrate a portion of the second buried dielectric layer 107 to come into connection with the backside source line 132B. Each of the second through vias 202 may penetrate a portion of the second buried dielectric layer 107, a corresponding active region AR, and a corresponding active pattern AP, and may be connected to the first source/drain pattern SD. The backside source line 132B may be electrically connected through the second through vias 202 to the first source/drain pattern SD.

Except for the mentioned above, a semiconductor device according to various example embodiments may be substantially the same as the semiconductor device discussed with reference to FIGS. 9 and 10.

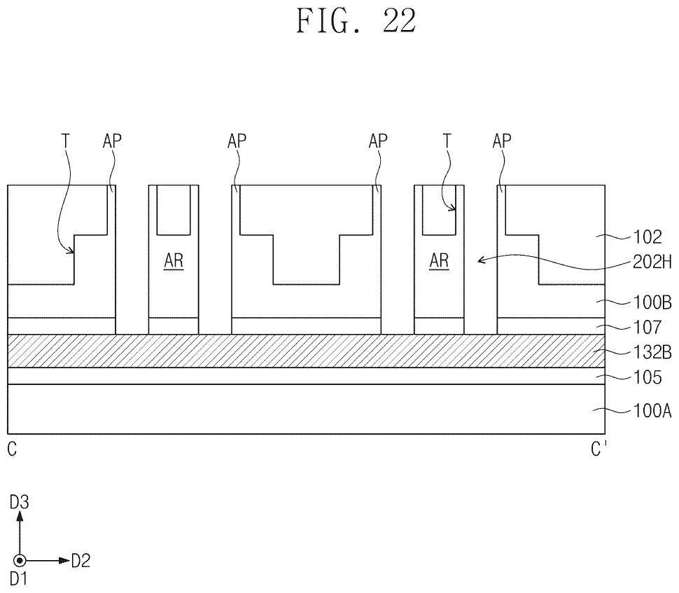

FIG. 22 illustrates a cross-sectional view taken along line C-C′ of FIG. 9, showing a method of fabricating a semiconductor device according to some example embodiments. For brevity of description, the following will mainly discuss a difference from the method of fabricating a semiconductor device discussed with reference to FIGS. 5A to 5C and 6A to 6C.

Referring to FIGS. 9 and 22, a first buried dielectric layer 105 may be formed on a lower substrate 100A, and the backside conductive lines 132B and 134B may be formed on the first buried dielectric layer 105. A second buried dielectric layer 107 may be formed on the first buried dielectric layer 105, thereby covering the backside conductive lines 132B and 134B. An upper substrate 100B may be formed on the second buried dielectric layer 107. The formation of the upper substrate 100B may include, for example, depositing on the second buried dielectric layer 107 one of a silicon layer, a germanium layer, and a silicon-germanium layer.

The trenches T may be formed on an upper portion of the upper substrate 100B to define the active regions AR and the active patterns AP. The device isolation layer 102 may be formed to fill the trenches T, and may be recessed to expose an upper portion of each active pattern AP. The sacrificial gate structure may be formed to run across the active patterns AP. Portions of each active pattern AP on opposite sides of the sacrificial gate structure may be recessed.

The second through via holes 202H may be formed to penetrate the upper substrate 100B and also to penetrate a portion of the second buried dielectric layer 107 to expose a top surface of the backside source line 132B. On one side of the sacrificial gate structure, each of the second through via holes 202H may penetrate a portion of the second buried dielectric layer 107, a corresponding active region AR, and a corresponding active pattern AP, and may expose the top surface of the backside source line 132B.

Referring back to FIGS. 9 and 21, the second through vias 202 may be formed to fill the second through via holes 202H. Thereafter, the source/drain patterns SD may be formed on the active patterns AP on opposite sides of the sacrificial gate structure. Each of the second through vias 202 may be connected to the first source/drain pattern SD of the source/drain patterns SD. The backside source line 132B may be electrically connected through the second through vias 202 to the first source/drain pattern SD.

Except for the mentioned above, a method of fabricating a semiconductor device according to various example embodiments may be substantially the same as the method of fabricating a semiconductor device discussed with reference to FIGS. 5A to 5C and 6A to 6C.

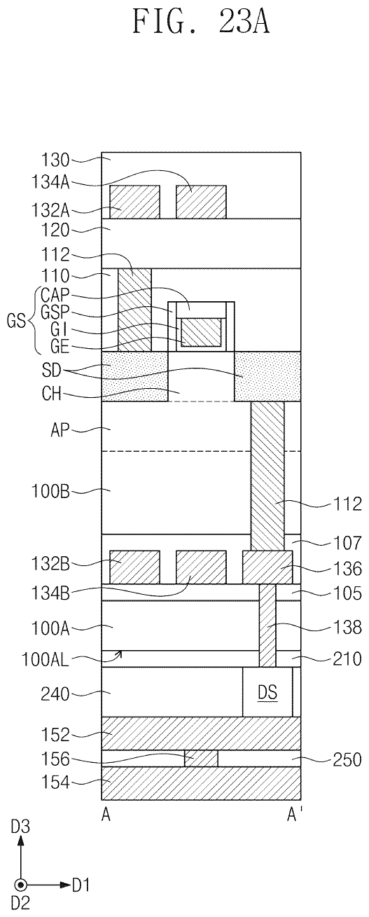

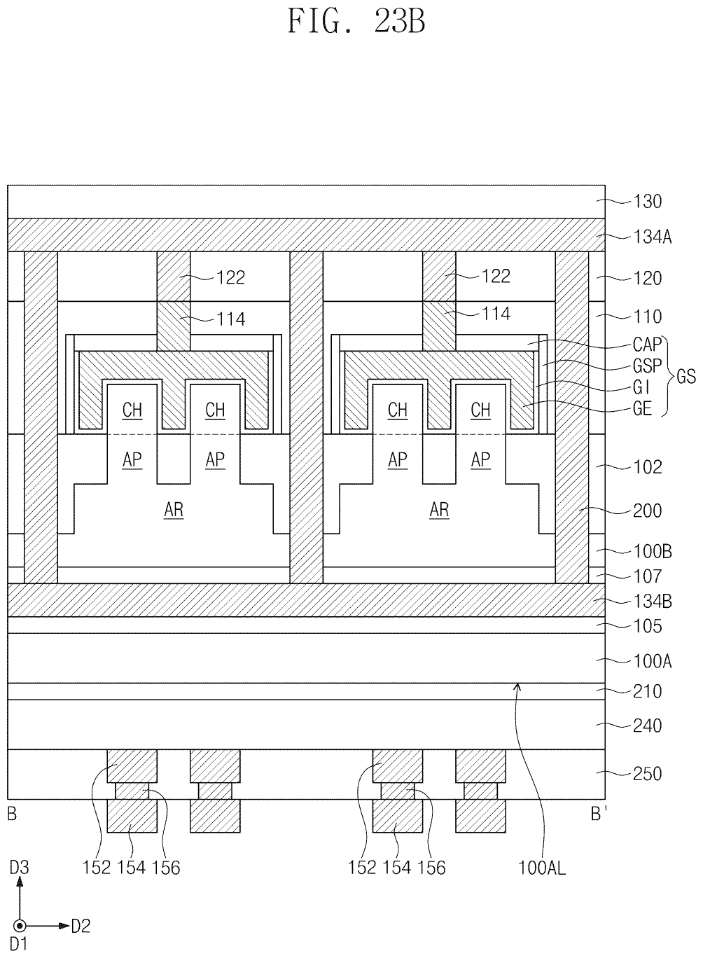

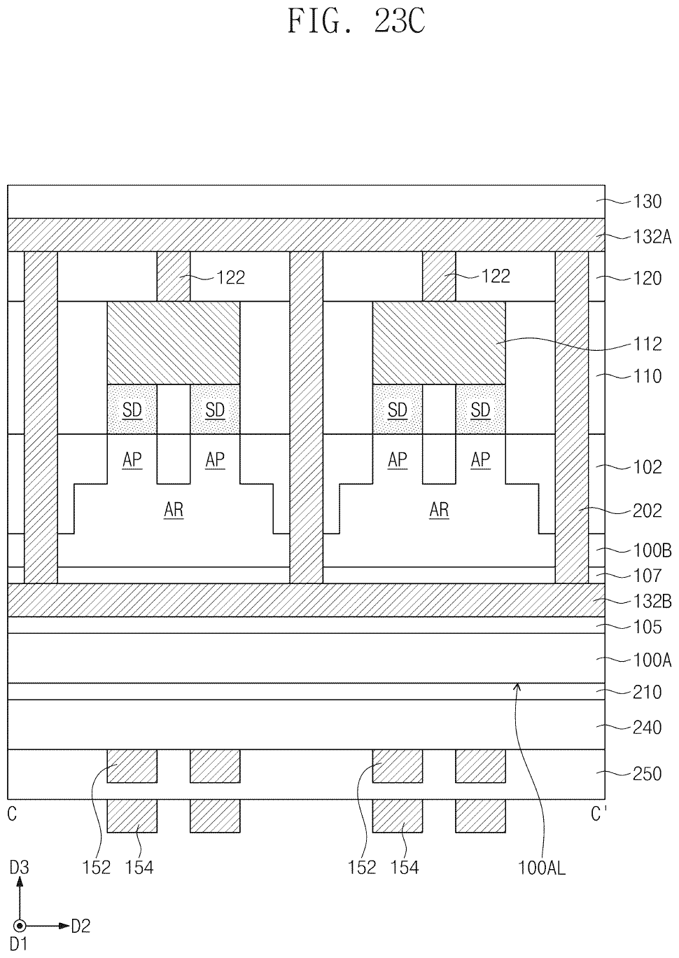

FIGS. 23A, 23B, and 23C illustrate cross-sectional views respectively taken along lines A-A′, B-B′, and C-C′ of FIG. 11, showing a semiconductor device according to some example embodiments. For brevity of description, the following will mainly discuss a difference from the semiconductor device discussed with reference to FIGS. 11 and 12A to 12C.

Referring to FIGS. 11 and 23A to 23C, a first buried dielectric layer 105 may be disposed on a lower substrate 100A, and the backside conductive lines 132B and 134B and the first conductive line 136 may be disposed on the first buried dielectric layer 105. A second buried dielectric layer 107 may be disposed on the first buried dielectric layer 105, and may cover the backside conductive lines 132B and 134B and the first conductive line 136. An upper substrate 100B may be disposed on the second buried dielectric layer 107. The upper substrate 100B may be substantially the same as the substrate 100 discussed with reference to FIGS. 2 and 3A to 3C. The first and second buried dielectric layers 105 and 107 may be called or referred to as a buried dielectric layer. The backside conductive lines 132B and 134B and the first conductive line 136 may be buried in the buried dielectric layer 105 and 107 between the lower substrate 100A and the upper substrate 100B.

Each of the through vias 200 and 202 may penetrate an upper portion of the second buried dielectric layer 107, the upper substrate 100B, the device isolation layer 102, the first interlayer dielectric layer 110, and the second interlayer dielectric layer 120, and may be connected to a corresponding one of the backside conductive lines 132B and 134B and a corresponding one of the frontside conductive lines 132A and 134A.

The second source/drain contact 112 of the source/drain contacts 112 may penetrate the upper substrate 100B and an upper portion of the second buried dielectric layer 107, and may be connected to the second source/drain pattern SD of the source/drain patterns SD. The second source/drain contact 112 may be connected to the first conductive line 136. The first conductive line 136 may be electrically connected through the second source/drain contact 112 to the second source/drain pattern SD.

The lower dielectric layer 210 may be disposed on a bottom surface 100AL of the lower substrate 100A. The data storage pattern DS may be disposed on the lower dielectric layer 210 and the bottom surface 100AL of the lower substrate 100A. The lower electrode contact 138 may penetrate the first buried dielectric layer 105, the lower substrate 100A, and the lower dielectric layer 210, and may be connected to the first conductive lines 136 and the data storage pattern DS. The data storage pattern DS may be electrically connected through the lower electrode contact 138 to the first conductive line 136. The data storage pattern DS may be electrically connected to the second source/drain pattern SD through the lower electrode contact 138, the first conductive line 136, and the second source/drain contact 112.

The second lower interlayer dielectric layer 240 may be disposed on the lower dielectric layer 210 and the bottom surface 100AL of the lower substrate 100A, and may cover the data storage pattern DS. The first cell conductive line 152 may be disposed on the second lower interlayer dielectric layer 240 and the bottom surface 100AL of the lower substrate 100A. The first cell conductive line 152 may be connected to the data storage pattern DS.

The third lower interlayer dielectric layer 250 may be disposed on the second lower interlayer dielectric layer 240 and the bottom surface 100AL of the lower substrate 100A, and may cover the first cell conductive line 152. The second cell conductive line 154 may be disposed on the third lower interlayer dielectric layer 250 and the bottom surface 100AL of the lower substrate 100A. The second via contact 156 may be disposed in the third lower interlayer dielectric layer 250, and may be interposed between the first cell conductive line 152 and the second cell conductive line 154.

Except for the mentioned above, a semiconductor device according to various example embodiments may be substantially the same as the semiconductor device discussed with reference to FIGS. 11 and 12A to 12C.

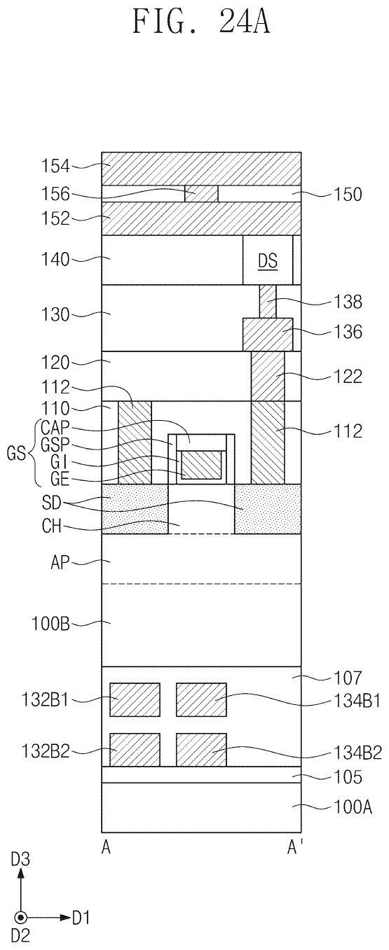

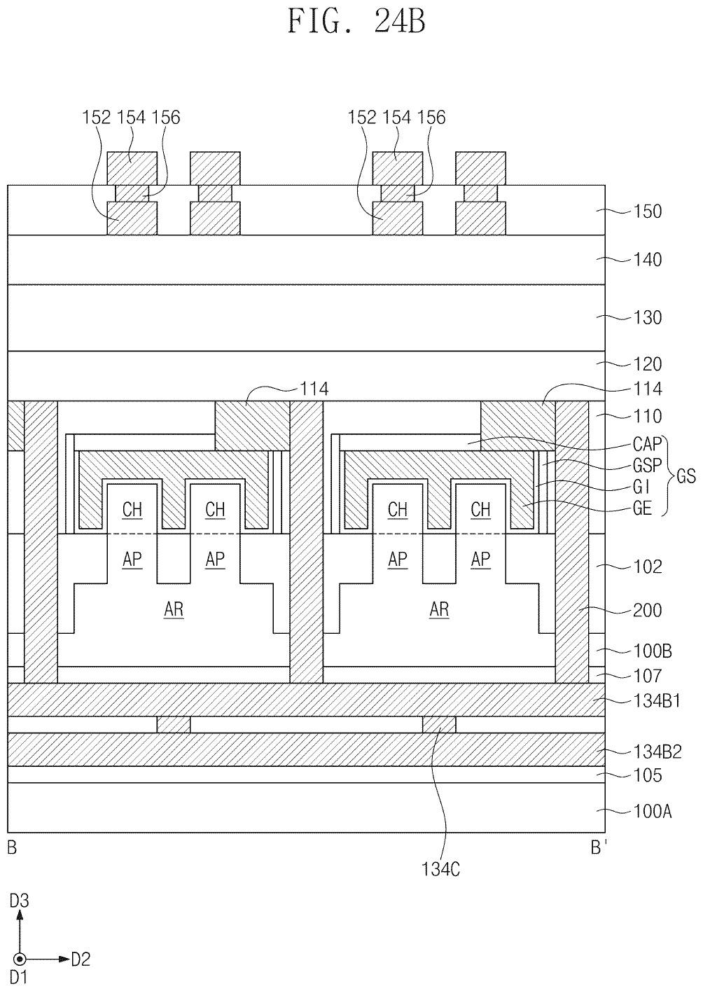

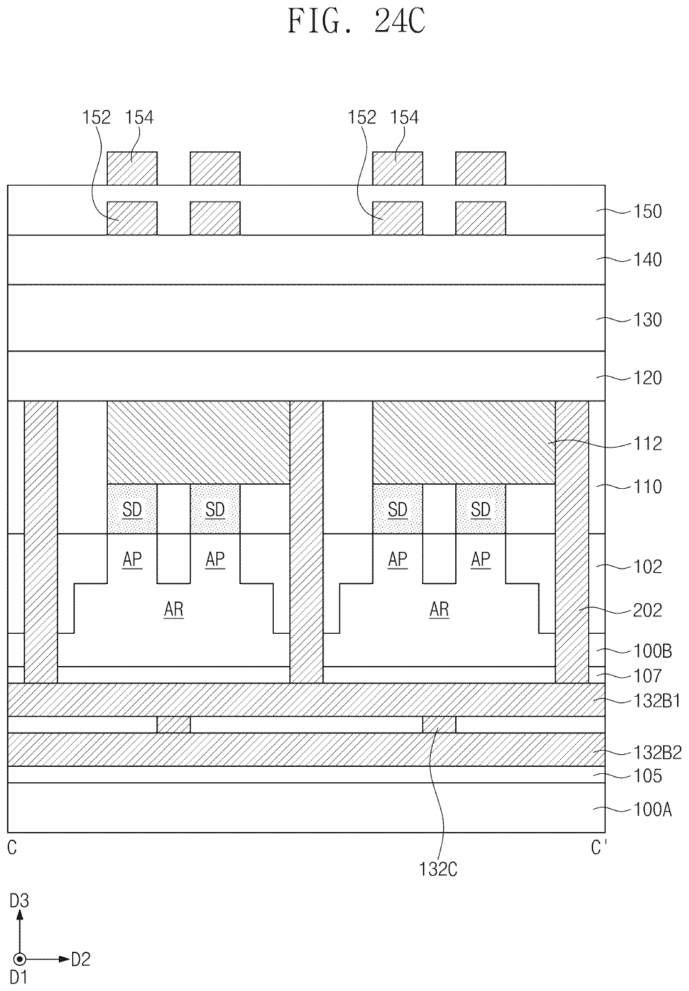

FIGS. 24A, 24B, and 24C illustrate cross-sectional views respectively taken along lines A-A′, B-B′, and C-C′ of FIG. 14, showing a semiconductor device according to some example embodiments. For brevity of description, the following will mainly discuss a difference from the semiconductor device discussed with reference to FIGS. 14 and 15A to 15C.

Referring to FIGS. 14 and 24A to 24C, a first buried dielectric layer 105 may be disposed on a lower substrate 100A, and the first backside conductive lines 132B1 and 134B1 and the second backside conductive lines 132B2 and 134B2 may be disposed on the first buried dielectric layer 105. A second buried dielectric layer 107 may be disposed on the first buried dielectric layer 105, and may cover the first and second backside conductive lines 132B1, 134B1, 132B2, and 134B2. An upper substrate 100B may be disposed on the second buried dielectric layer 107. The first and second buried dielectric layers 105 and 107 may be called a buried dielectric layer. The first and second backside conductive lines 132B1, 134B1, 132B2, and 134B2 may be buried in the buried dielectric layer 105 and 107 between the lower substrate 100A and the upper substrate 100B.

Each of the through vias 200 and 202 may penetrate an upper portion of the second buried dielectric layer 107, the upper substrate 100B, the device isolation layer 102, the first interlayer dielectric layer 110, and the second interlayer dielectric layer 120, and may be connected to a corresponding one of the first backside conductive lines 132B1 and 134B1.

The first backside contacts 132C may be disposed in the buried dielectric layer 105 and 107, and may be interposed between the first backside source line 132B1 of the first backside conductive lines 132B1 and 134B1 and the second backside source line 132B2 of the second backside conductive lines 132B2 and 134B2. The first backside source line 132B1 and the second backside source line 132B2 may be connected to each other through the first backside contacts 132C.

The second backside contacts 134C may be disposed in the buried dielectric layer 105 and 107, and may be interposed between the first backside word line 134B1 of the first backside conductive lines 132B1 and 134B1 and the second backside word line 134B2 of the second backside conductive lines 132B2 and 134B2. The first backside word line 134B1 and the second backside word line 134B2 may be connected to each other through the second backside contacts 134C.

Except for the mentioned above, a semiconductor device according to various example embodiments may be substantially the same as the semiconductor device discussed with reference to FIGS. 14 and 15A to 15C.

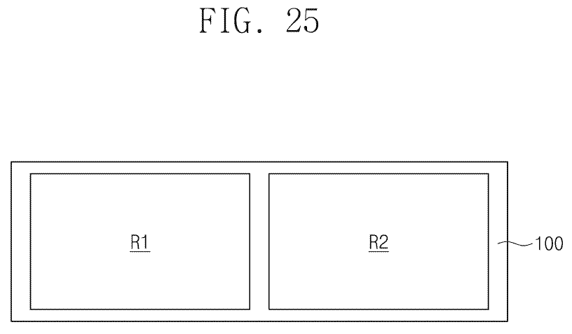

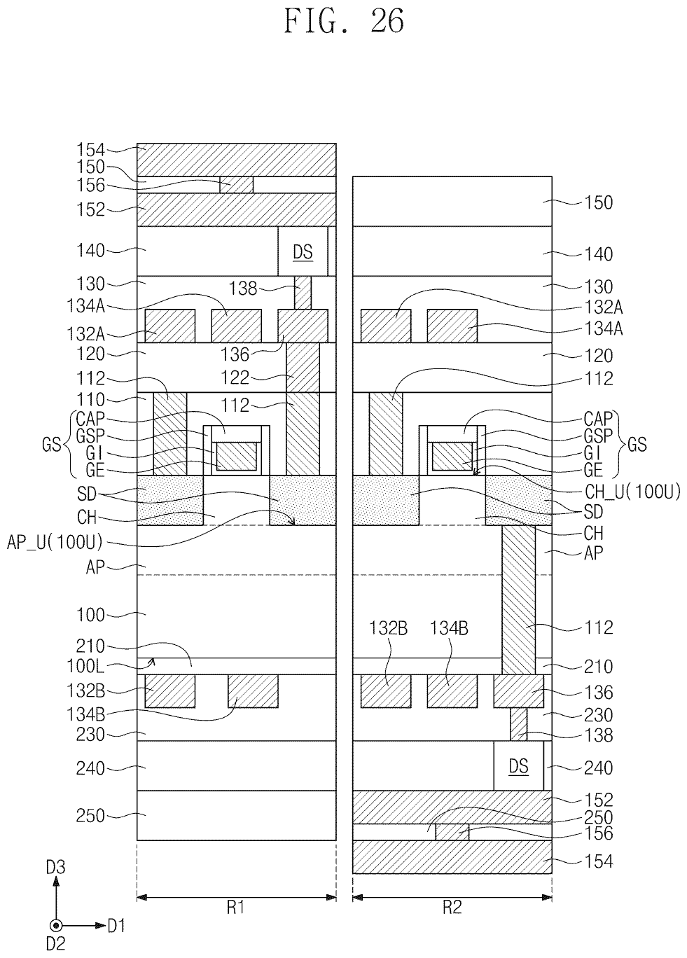

FIG. 25 illustrates a simplified plan view showing a semiconductor device according to some example embodiments. FIG. 26 illustrates a cross-sectional view showing components on a first region and a second region of FIG. 25.

Referring to FIGS. 25 and 26, the substrate 100 may include a first region R1 and a second region R2. The first region R1 of the substrate 100 may be configured substantially identically to the semiconductor device discussed with reference to FIGS. 2 and 3A to 3C, and the second region R2 of the substrate 100 may be configured substantially identically to the semiconductor device discussed with reference to FIGS. 11 and 12A to 12C.

According to some example embodiments, the data storage pattern DS on the first region R1 may be disposed on the third interlayer dielectric layer 130. The fourth interlayer dielectric layer 140 may cover the data storage pattern DS on the first region R1, and may extend onto the third interlayer dielectric layer 130 on the second region R2. The first cell conductive line 152 on the first region R1 may be disposed on the fourth interlayer dielectric layer 140. The fifth interlayer dielectric layer 150 may cover the first cell conductive line 152 on the first region R1, and may extend onto the fourth interlayer dielectric layer 140 on the second region R2. The second cell conductive line 154 on the first region R1 may be disposed on the fifth interlayer dielectric layer 150. The second via contact 156 on the first region R1 may be disposed in the fifth interlayer dielectric layer 150, and may be interposed between the first cell conductive line 152 and the second cell conductive line 154.

The backside conductive lines 132B and 134B on the first region R1 may be disposed on the bottom surface 100L of the substrate 100, and the lower dielectric layer 210 may be interposed between the bottom surface 100L of the substrate 100 and the backside conductive lines 132B and 134B. The backside conductive lines 132B and 134B and the first conductive line 136 on the second region R2 may be disposed on the bottom surface 100L of the substrate 100, and the lower dielectric layer 210 may extend between the bottom surface 100L of the substrate 100 and the backside conductive lines 132B and 134B and between the bottom surface 100L of the substrate 100 and the first conductive line 136.

The first lower interlayer dielectric layer 230 may cover the backside conductive lines 132B and 134B on the first region R1, and may also cover the first conductive line 136 and the backside conductive lines 132B and 134B on the second region R2.

The data storage pattern DS on the second region R2 may be disposed on the first lower interlayer dielectric layer 230 and the bottom surface 100L of the substrate 100. The lower electrode contact 138 on the second region R2 may be disposed in the first lower interlayer dielectric layer 230, and may be interposed between the data storage pattern DS and the first conductive line 136.

The second lower interlayer dielectric layer 240 may cover the data storage pattern DS on the second region R2, and may extend onto the first lower interlayer dielectric layer 230 on the first region R1. The first cell conductive line 152 on the second region R2 may be disposed on the second lower interlayer dielectric layer 240 and the bottom surface 100L of the substrate 100. The third lower interlayer dielectric layer 250 may cover the first cell conductive line 152 on the second region R2, and may extend onto the second lower interlayer dielectric layer 240 on the first region R1. The second cell conductive line 154 on the second region R2 may be disposed on the third lower interlayer dielectric layer 250 and the bottom surface 100L of the substrate 100. The second via contact 156 on the second region R2 may be disposed in the third lower interlayer dielectric layer 250, and may be interposed between the first cell conductive line 152 and the second cell conductive line 154.

The data storage pattern DS on the first region R1 and the data storage pattern DS on the second region R2 may each be configured substantially identically to the data storage pattern DS discussed with reference to FIGS. 4A and 4B. The data storage pattern DS on the first region R1 may include a first magnetic tunnel junction pattern, and the data storage pattern DS on the second region R2 may include a second magnetic tunnel junction pattern. The first magnetic tunnel junction pattern and the second magnetic tunnel junction pattern may have memory characteristics different from each other. For example, the first magnetic tunnel junction pattern and the second magnetic tunnel junction pattern may have different switching characteristics, and for example, a critical current density required for magnetization reversal of the first magnetic tunnel junction pattern may be different from that required for magnetization reversal of the second magnetic tunnel junction pattern. In this case, the first magnetic tunnel junction pattern and the second magnetic tunnel junction pattern may have different switching speeds or different retention properties. Alternatively, the first magnetic tunnel junction pattern and the second magnetic tunnel junction pattern may have different endurance properties. According to some example embodiments, one of the first and second magnetic tunnel junction patterns may serve as a storage memory cell (e.g., a nonvolatile memory (NVM) cell), and the other of the first and second magnetic tunnel junction patterns may serve as a cache memory cell (e.g., a random access memory (RAM) cell).

For example, a critical current density required for magnetization reversal of the first magnetic tunnel junction pattern may be less than that required for magnetization reversal of the second magnetic tunnel junction pattern. In this case, the first magnetic tunnel junction pattern may be easily switched more than the second magnetic tunnel junction pattern, and the second magnetic tunnel junction pattern may have retention properties greater than those of the first magnetic tunnel junction pattern. Therefore, the data storage pattern DS including the first magnetic tunnel junction pattern on the first region R1 may serve as a cache memory cell (e.g., a random access memory (RAM) cell), and the data storage pattern DS including the second magnetic tunnel junction pattern on the second region R2 may serve as a storage memory cell (e.g., a nonvolatile memory (NVM) cell).

According to various example embodiments, a transistor may be disposed on a top surface of a substrate, and at least one backside conductive line may be disposed on a bottom surface of the substrate. When a word line connected to a gate terminal (or a gate electrode) of the transistor includes the at least one backside conductive line and one of a frontside conductive line and an additional backside conductive line that are connected in parallel thereto, the word line may decrease in resistance. When a source line connected to a source terminal (or a first source/drain pattern) of the transistor includes the at least one backside conductive line and one of a frontside conductive line and an additional backside conductive line that are connected in parallel thereto, the source line may decrease in resistance. It therefore may be possible to provide a semiconductor device with improved electrical properties.

Alternatively or additionally, a data storage pattern connected to a drain terminal (or a second source/drain pattern) of the transistor may be disposed on the top or bottom surface of the substrate. The data storage pattern may include a magnetic tunnel junction pattern. Thus, magnetic tunnel junction patterns having different switching characteristics may be easily disposed on the top or bottom surface of the substrate. Accordingly, it may be possible to provide a semiconductor device including magnetic tunnel junction patterns with different switching characteristics.

The aforementioned description provides some example embodiments for explaining the present inventive concepts. Therefore, inventive concepts are not limited to the embodiments described above, and it will be understood by one of ordinary skill in the art that variations in form and detail may be made therein without departing from the spirit and essential features of the present inventive concepts. Additionally example embodiments are not necessarily mutually exclusive with one another. For example, some example embodiments may include one or more features described with reference to one or more figures, and may also include one or more other features described with reference to one or more other figures.

1. A semiconductor device, comprising:
a substrate having a top surface and a bottom surface opposite to each other;
a gate structure on the top surface of the substrate;
a plurality of source/drain patterns on the top surface of the substrate and on opposite sides of the gate structure;
a backside conductive line on the bottom surface of the substrate and electrically connected to at least one of the gate structure or a first source/drain pattern of the source/drain patterns; and
a magnetic tunnel junction pattern electrically connected to a second source/drain pattern of the source/drain patterns.

2. The semiconductor device of claim 1, further comprising:
a frontside conductive line on the top surface of the substrate and electrically connected to at least one of the first source/drain pattern or the gate structure,
wherein the frontside conductive line is at a height from the top surface of the substrate higher than a height of the gate structure and a height of the source/drain patterns.

3. The semiconductor device of claim 2, further comprising:
a through via penetrating at least a portion of the substrate,
wherein the frontside conductive line and the backside conductive line are connected to each other through the through via.

4. The semiconductor device of claim 3, further comprising:
a gate contact on the gate structure,
wherein the frontside conductive line and the backside conductive line are electrically connected to the gate structure through the through via and the gate contact.

5. The semiconductor device of claim 3, further comprising:
a first source/drain contact on the first source/drain pattern,
wherein the frontside conductive line and the backside conductive line are electrically connected to the first source/drain pattern through the through via and the first source/drain contact.

6. The semiconductor device of claim 2, further comprising:
a first source/drain contact between the first source/drain pattern and the frontside conductive line; and
a through via penetrating at least a portion of the substrate and interposed between the first source/drain pattern and the backside conductive line, wherein
the frontside conductive line is electrically connected through the first source/drain contact to the first source/drain pattern, and
the backside conductive line is electrically connected through the through via to the first source/drain pattern.

7. The semiconductor device of claim 1, further comprising:
a through via penetrating at least a portion of the substrate and connected to the backside conductive line,
wherein the backside conductive line is electrically connected through the through via to the first source/drain pattern or the gate structure.

8. The semiconductor device of claim 7, further comprising:
a first source/drain contact on the first source/drain pattern; and
a gate contact on the gate structure,
wherein the through via is connected to at least one of a lateral surface of the first source/drain contact or a lateral surface of the gate contact.

9. The semiconductor device of claim 7, further comprising:
an additional backside conductive line on the bottom surface of the substrate, the backside conductive line between the additional backside conductive line and the bottom surface of the substrate; and
a plurality of backside contacts between the backside conductive line and the additional backside conductive line,
wherein the backside conductive line and the additional backside conductive line are connected to each other through the plurality of backside contacts.

10. The semiconductor device of claim 1, further comprising:
a lower substrate; and
a buried dielectric layer between the lower substrate and the bottom surface of the substrate,
wherein the backside conductive line is buried in the buried dielectric layer.

11. A semiconductor device, comprising:
a substrate having a top surface and a bottom surface opposite to each other;
a gate structure on the top surface of the substrate;
a plurality of source/drain patterns on the top surface of the substrate and on opposite sides of the gate structure;
a frontside conductive line on the top surface of the substrate and electrically connected to at least one of the gate structure or a first source/drain pattern of the source/drain patterns;
a backside conductive line on the bottom surface of the substrate and electrically connected to the first source/drain pattern or the gate structure; and
a through via penetrating at least a portion of the substrate and connected to the backside conductive line and the frontside conductive line.

12. The semiconductor device of claim 11, further comprising:
a gate contact on the gate structure,
wherein the frontside conductive line and the backside conductive line are electrically connected to the gate structure through the through via and the gate contact.

13. The semiconductor device of claim 12, wherein the through via is in contact with a lateral surface of the gate contact.

14. The semiconductor device of claim 12, further comprising:
a first source/drain contact on the first source/drain pattern,
wherein the frontside conductive line and the backside conductive line are electrically connected to the first source/drain pattern through the through via and the first source/drain contact.

15. The semiconductor device of claim 14, wherein the through via is in contact with a lateral surface of the first source/drain contact.

16. The semiconductor device of claim 11, further comprising:
a data storage pattern on the top surface of the substrate and electrically connected to a second source/drain pattern of the source/drain patterns.

17. The semiconductor device of claim 11, further comprising:
a data storage pattern on the bottom surface of the substrate and electrically connected to a second source/drain pattern of the source/drain patterns.

18. A semiconductor device, comprising:
a substrate having a top surface and a bottom surface opposite to each other, the substrate including a first region and a second region horizontally spaced apart from each other;
a first transistor on the top surface of the first region of the substrate;
a first magnetic tunnel junction pattern on the top surface of the first region of the substrate and connected to a first drain terminal of the first transistor;
a first backside conductive line on the bottom surface of the first region of the substrate and connected to at least one of a first source terminal and a first gate terminal of the first transistor;
a second transistor on the top surface of the second region of the substrate; and
a second magnetic tunnel junction pattern on the bottom surface of the second region of the substrate and connected to a second drain terminal of the second transistor.

19. The semiconductor device of claim 18, further comprising:
a first frontside conductive line on the top surface of the first region of the substrate and connected to at least one of the first source terminal and the first gate terminal of the first transistor.

20. The semiconductor device of claim 19, further comprising:
a second frontside conductive line on the top surface of the second region of the substrate and connected to at least one of a second source terminal and a second gate terminal of the second transistor.

21.-22. (canceled)
